(19) United States
(12) Patent Application Publication
(10) Pub. No.: US 2024/0268190 A1
(43) Pub. Date: Aug. 8, 2024

(54) DISPLAY PANEL AND METHOD OF FARICATING THE SAME

(71) Applicant: Samsung Display Co., LTD., Yongin-si (KR)

(72) Inventor: SUNGMIN HUR, Yongin-si (KR)

(21) Appl. No.: 18/387,602

(22) Filed: Nov. 7, 2023

(30) Foreign Application Priority Data
Feb. 6, 2023 (KR) 10-2023-0015826

(51) Int. Cl. H10K 59/80; H10K 59/40; H10K 71/20

(52) U.S. Cl. CPC H10K 59/873; H10K 59/40; H10K 71/20

(57) ABSTRACT

A display panel includes a base layer that includes a display area and a non-display area adjacent to the display area, a plurality of emission elements on the display area, and an encapsulation layer that includes an organic layer and an inorganic layer in contact with a bottom surface of the organic layer. The organic layer may be on the plurality of emission elements. The inorganic layer may include an oxygen atom and a silicon atom. In the inorganic layer, a top surface of a portion that overlaps the display area and a top surface of a portion that overlaps the non-display area have a substantially identical surface roughness.

This application claims priority to Korean Patent Application No. 10-2023-0015826, filed on Feb. 6, 2023, and all the benefits accruing therefrom under 35 U.S.C. § 119, the content of which in its entirety is herein incorporated by reference.

### BACKGROUND

### 1. Field

Embodiments of the disclosure relate to a display panel and a method of fabricating the same, and more particularly, to a display panel having increased accuracy and a method of fabricating the same.

### 2. Description of the Related Art

Among display devices, an organic light-emitting display device may include an organic material. To protect an organic material vulnerable to oxygen and moisture, various techniques are developed to encapsulate the organic light-emitting display device. Thin film encapsulation technology is a technique in which an encapsulation layer is disposed on an organic emission element to block penetration paths of air and moisture. An encapsulation layer may include a structure in which at least one inorganic layer including an inorganic material is alternately stacked on at least one organic layer including an organic material.

### SUMMARY

Embodiments of the disclosure provide a display panel having increased accuracy and a method of fabricating the same.

In an embodiment of the disclosure, a display panel includes: a base layer that includes a display area and a non-display area adjacent to the display area; a plurality of emission elements on the display area; and an encapsulation layer that includes an organic layer and an inorganic layer in contact with a bottom surface of the organic layer, the organic layer being on the plurality of emission elements, and the inorganic layer including an oxygen atom and a silicon atom. In the inorganic layer, a top surface of a portion that overlaps the display area and a top surface of a portion that overlaps the non-display area may have a substantially identical surface roughness.

In an embodiment, the inorganic layer may include: a lower layer; and an upper layer on the lower layer. A ratio of the oxygen atom to the silicon atom in the upper layer may be greater than a ratio of the oxygen atom to the silicon atom in the lower layer.

In an embodiment, the display panel may further include: a first dam spaced apart from the plurality of emission elements; and a second dam farther away than the first dam from the plurality of emission elements. The organic layer may extend between the first dam and the second dam.

In an embodiment, the substantially identical surface roughness equals to about 4 nanometers (nm).

In an embodiment, the ratio of the oxygen atom to the silicon atom in the upper layer may be in a range of about 1.5 to about 5.

In an embodiment of the disclosure, a method of fabricating a display panel includes: providing a mother substrate on which is formed an organic emission element that includes an anode, an emission layer, and a cathode on a display area; providing the mother substrate with plasma; providing the display area with a deposition gas to form a preliminary inorganic layer; stopping providing the deposition gas; removing at least a portion of the preliminary inorganic layer to form an inorganic layer; and removing the plasma. The at least a portion of the preliminary inorganic layer may be removed with the plasma.

In an embodiment, the operation of removing the plasma may be performed after an elapse of a predetermined time from the supply stop of the deposition gas. The predetermined time may be a time taken until the inorganic layer has a surface roughness of about 4 nm.

In an embodiment, the operation of removing the plasma may be performed after an elapse of a predetermined time from the supply stop of the deposition gas. The predetermined time may be in a range of about 0.5 second to about 2 seconds.

In an embodiment, the mother substrate may further include a non-display area adjacent to the display area.

In the inorganic layer, a top surface of a portion that overlaps the display area and a top surface of a portion that overlaps the non-display area may have a substantially identical surface roughness.

In an embodiment, the deposition gas may include a silane (SiH₄) gas.

In an embodiment, the preliminary inorganic layer may include: a lower layer; an upper layer on the lower layer; and at least one silicon pattern on the upper layer. The removed portion of the preliminary inorganic layer may include the silicon pattern.

In an embodiment, the operation of forming the preliminary inorganic layer may include providing the deposition gas until the upper layer has a predetermined ratio of oxygen atoms to silicon atoms. The predetermined ratio may be in a range of about 1.5 to about 5.

In an embodiment, the method may further include proving a liquid monomer on the inorganic layer to form an organic layer.

In an embodiment, the mother substrate may further include: a first dam on the mother substrate and spaced apart from the organic emission element; and a second dam on the mother substrate and farther away than the first dam from the organic emission element. The liquid monomer may have fluidity capable of extending between the first dam and the second dam.

In an embodiment of the disclosure, a method of fabricating a display panel may include: providing a mother substrate on which is formed an organic emission element that includes an anode, an emission layer, and a cathode on a display area; providing the mother substrate with plasma; providing the display area with a deposition gas to form a preliminary inorganic layer; stopping providing the deposition gas; removing at least a portion of the preliminary inorganic layer to form an inorganic layer; and removing the plasma. The operation of removing the plasma may be performed after stopping providing the deposition gas.

In an embodiment, the operation of removing the plasma may be performed after an elapse of a predetermined time from the supply stop of the deposition gas. The predetermined time may be in a range of about 0.5 second to about 2 seconds.

In an embodiment, a surface roughness of the inorganic layer may be equal to or less than about 4 nm.

In an embodiment, the mother substrate may further include a non-display area adjacent to the display area.

In the inorganic layer, a top surface of a portion that overlaps the display area and a top surface of a portion that overlaps the non-display area may have a substantially identical surface roughness.

In an embodiment, the preliminary inorganic layer may include: a lower layer; an upper layer on the lower layer; and a silicon pattern on the upper layer. A ratio of oxygen atoms to silicon atoms in the upper layer may be greater than a ratio of oxygen atoms to silicon atoms in the lower. The removed portion of the preliminary inorganic layer may include the silicon pattern.

In an embodiment, the operation of forming the preliminary inorganic layer may include providing the deposition gas such that the ratio of oxygen atoms to silicon atoms in the upper layer may have a range of about 1.5 to about 5.

### BRIEF DESCRIPTION OF DRAWINGS

The above and other exemplary embodiments, advantages and features of this disclosure will become more apparent by describing in further detail exemplary embodiments thereof with reference to the accompanying drawings, in which:

FIG. 1A illustrates an assembled perspective view showing an embodiment of a display device according to the disclosure.

FIG. 1B illustrates an exploded perspective view showing an embodiment of a display device according to the disclosure.

FIG. 2 illustrates a cross-sectional view showing an embodiment of a display device according to the disclosure.

FIG. 3 illustrates a plan view showing an embodiment of a display panel according to the disclosure.

FIG. 4A illustrates a cross-sectional view showing an embodiment of an input sensing unit according to the disclosure.

FIG. 4B illustrates a plan view showing an embodiment of an input sensing unit according to the disclosure.

FIG. 5 illustrates a cross-sectional view showing an embodiment of a display module according to the disclosure.

FIG. 6 illustrates a simplified diagram showing an embodiment of a deposition apparatus according to the disclosure.

FIGS. 7A and 7B illustrate flow charts showing an embodiment of a method of fabricating a display panel according to the disclosure.

FIG. 8 illustrates a plan view showing an embodiment of a substrate according to the disclosure.

FIG. 9 illustrates a plan view partially showing an embodiment of a substrate according to the disclosure.

FIGS. 10A to 10D illustrate cross-sectional views showing an embodiment of some operations of a method of fabricating a display panel according to the disclosure.

FIGS. 11A to 11C illustrates diagrams showing an embodiment of a comparative embodiment of a display panel according to the disclosure.

FIGS. 12A to 12C illustrate diagrams showing an embodiment of an experimental embodiment of a display panel according to the disclosure.

FIGS. 13A to 13D illustrate graphs showing the degree of dispersion of an organic material in a display panel according to a comparative embodiment of the disclosure.

FIGS. 14A to 14D illustrate graphs showing the degree of dispersion of an organic material in a display panel according to an experimental embodiment of the disclosure.

### DETAILED DESCRIPTION OF EMBODIMENTS

In this description, when a certain component (or region, layer, portion, etc.) is referred to as being “on”, “connected to”, or “coupled to” other component(s), the certain component may be directly on, directly connected to, or directly coupled to the other component(s) or at least one intervening component may be therebetween.

Like numerals indicate like components. Moreover, in the drawings, thicknesses, ratios, and dimensions of components are exaggerated for effectively explaining the technical contents. The term “and/or” includes one or more combinations defined by associated components.

It will be understood that, although the terms first, second, etc. may be used herein to describe various components, these components should not be limited by these terms. These terms are only used to distinguish one component from another component. For example, a first component could be termed a second component, and vice versa without departing from the scope of the present disclosure. Unless the context clearly indicates otherwise, the singular forms are intended to include the plural forms as well.

In addition, the terms “beneath”, “lower”, “above”, “upper”, and the like are used herein to describe one component's relationship to other component(s) illustrated in the drawings. The relative terms are intended to encompass different orientations in addition to the orientation depicted in the drawings.

It should be understood that the terms “comprise”, “include”, “have”, and the like are used to specify the presence of stated features, integers, steps, operations, components, elements, or combinations thereof, but do not preclude the presence or addition of one or more other features, integers, steps, operations, components, elements, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term “about” can mean within one or more standard deviations, or within +30%, 20%, 10%, 5% of the stated value, for example.

Unless otherwise defined, all terms used herein including technical and scientific terms have the same meaning generally understood by one of ordinary skilled in the art. Also, terms as defined in dictionaries generally used should be understood as having meaning identical or meaning contextually defined in the art and should not be understood as ideally or excessively formal meaning unless definitely defined herein.

With reference to the accompanying drawings, the following will describe a display panel and a method of fabricating the same according to the disclosure.

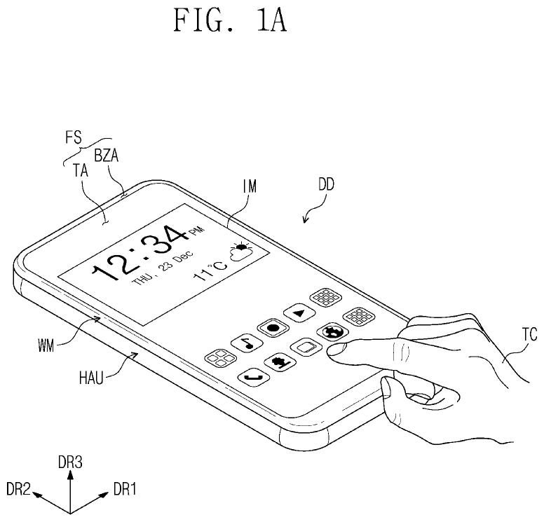

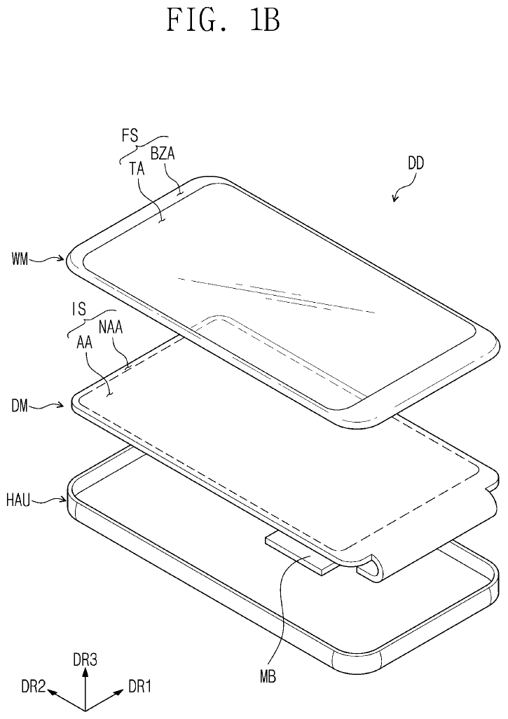

FIG. 1A illustrates an assembled perspective view showing an embodiment of a display device according to the disclosure.

Referring to FIGS. 1A and 1B, a display device DD may be an apparatus activated with an electrical signal. The display device DD may display an image IM and detect an external input TC. The display device DD may include various embodiments. In an embodiment, the display device DD may include a tablet computer, a laptop computer, a desktop computer, or a smart television set, for example. In the illustrated embodiment, a smart phone is illustrated as the display device DD.

The display device DD may display the image IM in a third direction DR3 on a display surface FS parallel to each of a first direction DR1 and a second direction DR2. The display surface FS on which the image IM is displayed may correspond to a front surface of the display device DD and a front surface of a window member WM. The same reference symbol is disposed to the display surface of the display device DD, the front surface of the display device DD, and the front surface of the window member WM. The image IM may include not only dynamic images but also static images. FIG. 1A depicts a clock and a plurality of icons as embodiments of the image IM.

In the illustrated embodiment, front and rear surfaces (or top and bottom surfaces) of each component are defined based on a direction along which the image IM is displayed. The front and rear surfaces may be opposite to each other in the third direction DR3, and a normal direction to each of the front and rear surfaces may be parallel to the third direction DR3. An interval in the third direction DR3 between the front and rear surfaces may correspond to a thickness in the third direction DR3 of the display device DD. Directions indicated by the first, second, and third directions DR1, DR2, and DR3 may be relative concepts and changed into other directions.

The display device DD in an embodiment of the disclosure may detect the external input (e.g., an input from a user) TC externally applied. The external input TC may include a part of user's body, light, heat, pressure, or any various types of input. In the illustrated embodiment, the external input TC is illustrated as a user's hand applied to the front surface FS. This, however, is merely an illustrative embodiment, and the external TC may be provided in various types as discussed above. Based on a structure of the display device DD, the display device DD may detect the external input TC applied to a lateral or rear surface thereof, but the disclosure is not limited thereto.

As shown in FIGS. 1A and 1B, the display device DD may include a window member WM, a display module DM, and an outer casing HAU. In the illustrated embodiment, the window member WM and the outer casing HAU may be combined to constitute an appearance of the display device DD. In the illustrated embodiment, the outer casing HAU, the display module DM, and the window member WM may be sequentially stacked along the third direction DR3.

The window member WM may include a dielectric panel. In an embodiment, the window member WM may include glass, plastic, or any combinations thereof, for example.

As discussed above, the front surface FS of the window member WM defines the front surface of the display device DD. A transmission area TA may be an optically transparent region. In an embodiment, the transmission area TA may be a region whose visible-light transmittance is equal to or greater than about 90%, for example.

A bezel area BZA may be a region whose optical transmittance is relatively lower than that of the transmission area TA. The bezel area BZA may define a shape of the transmission area TA. The bezel area BZA may be adjacent to and may surround the transmission area TA.

The bezel area BZA may have a predetermined color. The bezel area BZA may cover a peripheral area NAA of the display module DM and may prevent the peripheral area NAA from being externally visible. This, however, is illustrative, and the bezel area BZA may be omitted from the window member WM according to the disclosure.

The display module DM may display the image IM and detect the external input TC. The image IM may be displayed on a front surface FS of the display module DM. The front surface IS of the display module DM may include an active area AA and a peripheral area NAA. The active area AA may be a region activated with an electrical signal.

In the illustrated embodiment, the active area AA may be a region that not only displays the image IM but also detects the external input TC. The transmission area TA may overlap the active area AA. In an embodiment, the transmission area TA may overlap an entirety or at least a portion of the active area AA, for example. Accordingly, a user may recognize the image IM through the transmission area TA or may provide the external input TC through the transmission area TA. This, however, is merely an illustrative embodiment. The active area AA may be configured such that a region to display the image IM may be separated from a region to detect the external input TC, but the disclosure is not limited thereto.

The peripheral area NAA may be a region covered with the bezel area BZA. The peripheral area NAA may be adjacent to the active area AA. The peripheral area NAA may surround the active area AA. The peripheral area NAA may include a driver line or a driver circuit for driving the active area AA.

The display module DM may include a display panel and an input sensing unit. The image IM may be substantially displayed on the display panel, and the external input TC may be substantially detected by the input sensing unit. As the display module DM includes both of the display panel and the input sensing unit, the display module DM may display the image IM and detect the external input TC. A detailed description thereof will be further discussed below.

At least a portion of the display module DM may be bendable. In the illustrated embodiment, the display module DM may include a portion to which a circuit board MB is coupled and which is bended toward a rear surface of the display module DM, and the circuit board MB may be assembled overlapping the rear surface of the display module DM.

The display device DD may further include the circuit board MB coupled to the display module DM. The circuit board MB may be combined with one side of the display module DM, and may be physically and electrically connected to the display module DM. The circuit board MB may generate an electrical signal provided to the display module DM or receive a single generated from the display module DM to be calculated into an outcome value including information of sensing magnitude or position of the external input TC.

The window member WM and the outer casing HAU may be combined to constitute an appearance of the display device DD. The outer casing HAU may provide an internal space. The display module DM may be accommodated in the internal space.

The outer casing HAU may include a material having relatively high strength. In an embodiment, the outer casing HAU may include glass, plastic, or metal, or may include a plurality of frames and/or plates including any combination of glass, plastic, and metal, for example. The outer casing HAU may stably protect, from external impact, components of the display device DD that are accommodated in the internal space.

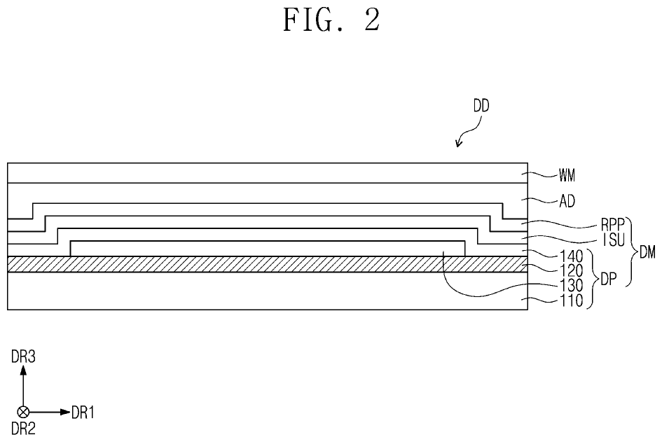

FIG. 2 illustrates a cross-sectional view showing an embodiment of a display device according to the disclosure.

Referring to FIG. 2, the display device DD may include a display panel DP, an input sensing unit ISU, an anti-reflector RPP, and a window member WM.

The display panel DP may be an emissive display panel, e.g., an organic light-emitting display panel, an inorganic light-emitting display panel, a quantum-dot display panel, a micro-light-emitting diode (“micro-LED”) display panel, or a nano-LED display panel. The display panel DP may include a base layer 110, a circuit layer 120, an emission element layer 130, and an encapsulation layer 140.

The base layer 110 may provide a base surface on which the circuit layer 120 is disposed. The base layer 110 may be a rigid substrate or a flexible substrate capable of being bendable, foldable, or rollable. The base layer 110 may be a glass substrate, a metal substrate, or a polymer substrate. The disclosure, however, is not limited thereto, and the base layer 110 may be an inorganic layer, an organic layer, or a composite material layer.

The base layer 110 may have a multi-layered structure. In an embodiment, the base layer 110 may include a first synthetic resin layer, an inorganic layer having a multi-layered or single-layered structure, and a second synthetic layer disposed on the inorganic layer having the multi-layered or single-layered structure, for example. Each of the first and second synthetic resin layers may include a polyimide-based resin, but the disclosure is not limited thereto.

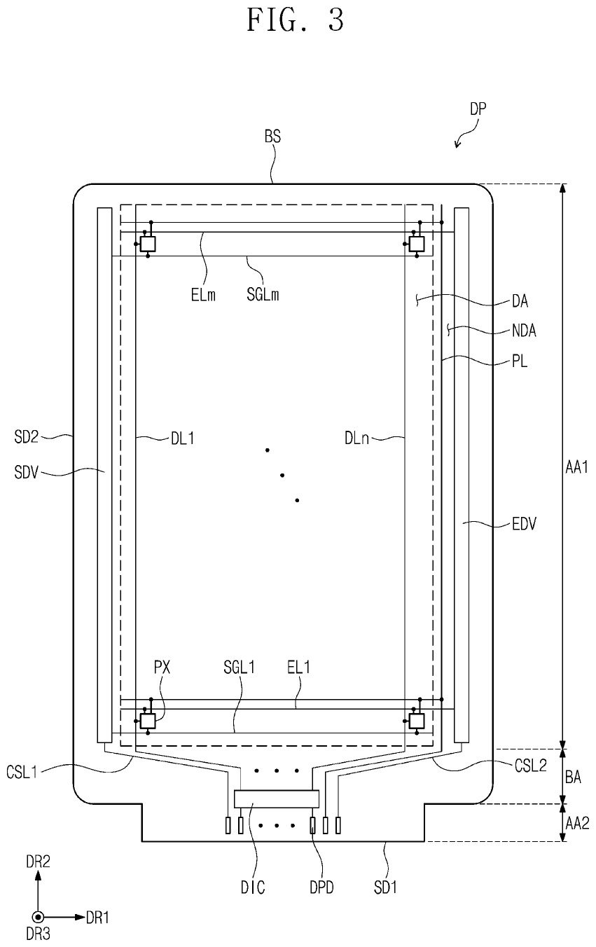

The circuit layer 120 may be disposed on the base layer 110. The circuit layer 120 may include a dielectric layer, a semiconductor pattern, a conductive pattern, and a signal line. The circuit layer 120 may include a driver circuit of a pixel (refer to PX of FIG. 3) which will be discussed below.

The emission element layer 130 may be disposed on the circuit layer 120. The emission element layer 130 may include an emission element of a pixel (refer to PX of FIG. 3) which will be discussed below. In an embodiment, the emission element may include an organic light-emitting material, an inorganic light-emitting material, an organic-inorganic light-emitting material, a quantum dot, a quantum rod, a micro-LED, or a nano-LED, for example.

The encapsulation layer 140 may be disposed on the emission element layer 130. The encapsulation layer 140 may protect the emission element layer 130 against moisture, oxygen, and foreign substances such as dust particles. The encapsulation layer 140 may include at least one inorganic layer. The encapsulation layer 140 may include a stack structure in which an inorganic layer, an organic layer, and an inorganic layer are stacked on each other.

The input sensing unit ISU may be disposed on the display panel DP. The input sensing unit ISU may detect an input externally applied. The external input may be a user's input. The user's input may include various types of external input such as a part of user's body, light, heat, pen, and pressure.

A series of processes may be employed to form the input sensing unit ISU on the display panel DP. In this case, the input sensing unit ISU may be directly disposed on the display panel DP. In this description, the phrase “A component is directly disposed on B component” may mean that no third component is disposed between A component and B component. In an embodiment, no adhesion layer may be disposed between the input sensing unit ISU and the display panel DP, for example.

The anti-reflector RPP may be disposed on the input sensing unit ISU. The anti-reflector RPP may reduce a reflectance of external light. A series of processes may be employed to form the anti-reflector RPP on the input sensing unit ISU.

The anti-reflector RPP may include a light-shield pattern that overlaps a reflection structure disposed below the anti-reflector RPP. The anti-reflector RPP may further include a color filter that overlaps an emission area which will be discussed below. The color filter may include a first color filter, a second color filter, and a third color filter that correspond to a first color pixel, a second color pixel, and a third color pixel.

The window member WM may be disposed on the anti-reflector RPP. The window member WM and the anti-reflector RPP may be bonded through an adhesion layer AD. The adhesion layer AD may be a pressure sensitive adhesive (“PSA”) or an optically clear adhesive (“OCA”).

The window member WM may include at least one base layer. The base layer may be a glass substrate or a synthetic resin film. The window member WM may have a multi-layered structure. The window member WM may include a thin glass substrate and a synthetic resin film disposed on the thin glass substrate. The thin glass substrate and the synthetic resin film may be bonded through an adhesion layer, and the adhesion layer and the synthetic resin film may be separated from the thin glass substrate for replacement thereof.

In an embodiment of the disclosure, the adhesion layer AD may be omitted, and the window member WM may be directly disposed on the anti-reflector RPP. The anti-reflector RPP may be coated thereon with an organic material, an inorganic material, or a ceramic material.

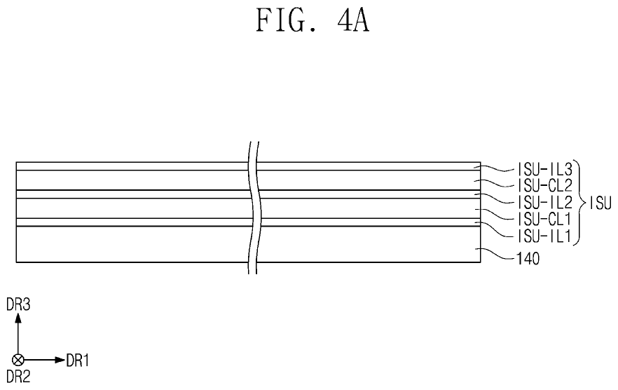

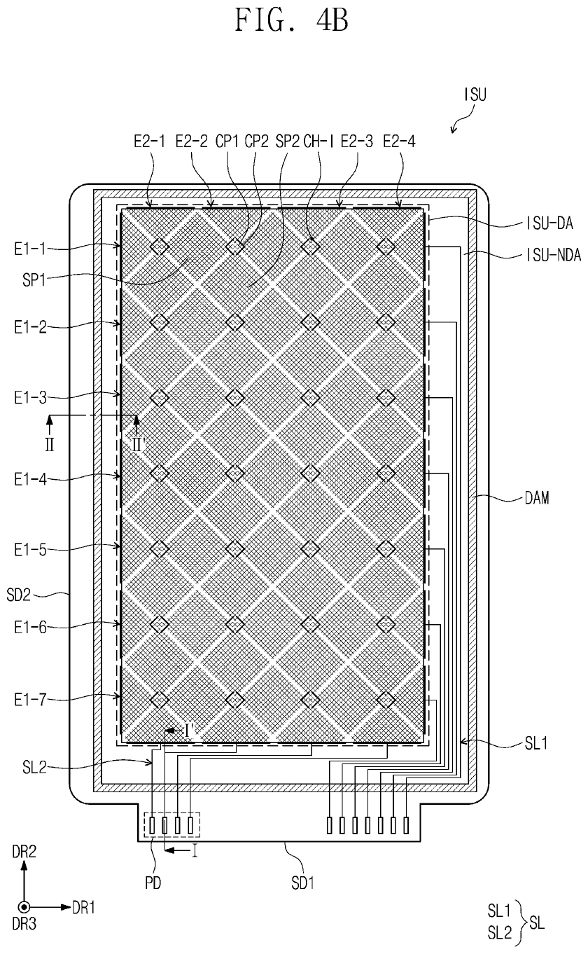

FIG. 3 illustrates a plan view showing an embodiment of a display panel according to the disclosure. FIG. 4A illustrates a cross-sectional view showing an embodiment of an input sensing unit according to the disclosure. FIG. 4B illustrates a plan view showing an embodiment of an input sensing unit according to the disclosure.

Referring to FIGS. 2, 3, 4A, and 4B, the display module DM may include the display panel DP and the input sensing unit ISU. The display panel DP may generate the image IM. In FIG. 3, some of components included in the display panel DP are illustrated when viewed in plan.

In FIG. 3, for easy description, some components of the display panel DP will be illustrated as being of convex shapes. Referring to FIG. 3, the display panel DP may include a base layer BS, a scan driver circuit SDV, an emission driver circuit EDV, a driver chip DIC, a plurality of panel signal lines SGL1 to SGLm, DL1 to DLn, EL1 to ELm, CSL1, CSL2, and PL, a plurality of pixels PX, and a plurality of display pads DPD.

The base layer BS may include a first base area AA1, a second base area AA2, and a bending area BA that are distinguished from each other in the second direction DR2. The second base area AA2 and the bending area BA may be a portion of a non-display area NDA. The bending area BA may be disposed between the first base area AA1 and the second base area AA2.

The first base area AA1 may be a region including the front surface IS of FIG. 1B. The second base area AA2 may be spaced apart from the first base area AA1 across the bending area BA. The second base area AA2 and the bending area BA may have a width in the first direction DR1 than that of the first base area AA1. In an embodiment, a length in the first direction DR1 of each of the bending area BA and the second base area AA2 may be less than that of the first base area AA1, for example.

It may be relatively easy to bend an area having a relatively small length in a direction parallel to a bending axis. This, however, is an illustrative embodiment, and the second base area AA2 and the bending area BA may have the same width in the second direction DR2 as that of the first base area AA1, but the disclosure is not limited to a particular embodiment.

The bending area BA may bend about a bending axis that extends along the first direction DR1. When the bending area BA does not band, the second base area AA2 may be directed in the same direction as that of the first base area AA1, and when the bending area BA is bent, the second base area AA2 may be directed in a direction opposite to that of the first base area AA1.

The circuit board (refer to MB of FIG. 1B) may be physically connected to the second base area AA2. As the bending area BA is bent, the circuit board MB may be disposed on a rear surface of the display panel DP. Therefore, a region that defines the front surface IS may become the first base area AA1, and neither the second base area AA2 nor the bending area BA may be visible through the front surface IS. Accordingly, the display device DD may have a reduced bezel area.

Each of the pixels PX may include an emission element and a thin film transistor connected to the emission element. The display panel DP shown in FIG. 3 may have a shape substantially the same as a planar shape of the base layer 110 discussed above. In the illustrated embodiment, a display area DA and a non-display area NDA may be distinguished based on whether the emission element is disposed or not.

FIG. 3 depicts that the pixels PX are disposed on the display area DA. The display area DA may be a region on which the image IM is displayed. This, however, is an illustrative embodiment. In an embodiment, one of components included in each of the pixels PX may include a thin film transistor disposed on the non-display area NDA, for example, and the disclosure is not limited thereto.

The scan driver circuit SDV, the driver chip DIC, and the emission driver circuit EDV may be disposed on the non-display area NDA. The driver chip DIC may include a data driver circuit.

The panel signal lines SGL1 to SGLm, DL1 to DLn, EL1 to ELm, CSL1, CSL2, and PL may include a plurality of scan lines SGL1 to SGLm, a plurality of data lines DL1 to DLn, a plurality of emission lines EL1 to ELm, first and second control lines CSL1 and CSL2, and a power line PL. Among the panel signal lines SGL1 to SGLm, DL1 to DLn, EL1 to ELm, CSL1, CSL2, and PL, the data lines DL1 to DLn, the first and second control lines CSL1 and CSL2, and the power line PL may be connected to a plurality of display pads DPD. The subscripts “m” and “n” are natural numbers. The pixels PX may be connected to the scan lines SGL1 to SGLm, the data lines DL1 to DLn, and the emission lines EL1 to ELm.

The scan lines SGL1 to SGLm may extend in the first direction DR1 to be connected to the scan driver circuit SDV. The data lines DL1 to DLn may extend in the second direction DR2 and may be connected through the bending area BA to the driver chip DIC. The emission lines EL1 to ELm may extend in the first direction DR1 to be connected to the emission driver circuit EDV.

The power line PL may include a part that extends in the second direction DR2 and a part that extends in the first direction DR1. The part extending in the first direction DR1 may be disposed at a different layer from that of the part extending in the second direction DR2. The part extending in the second direction DR2 of the power line PL may extend through the bending area BA toward the second base area AA2. The power line PL may provide the pixels PX with a first voltage.

The first control line CSL1 may be connected to the scan driver circuit SDV, and may extend through the bending area BA toward a lower end of the second base area AA2. The second control line CSL2 may be connected to the emission driver circuit EDV, and may extend through the bending area BA toward the lower end of the second base area AA2.

When viewed in plan, the display pads DPD may be disposed adjacent to the lower end of the second base area AA2. The driver chip DIC, the power line PL, the first control line CSL1, and the second control line CSL2 may be connected to the display pads DPD. The display pads DPD may each be electrically connected through an anisotropic conductive adhesion layer to the circuit board MB.

Referring to FIG. 4A, the input sensing unit ISU may include a first sensing dielectric layer ISU-IL1 (or a base dielectric layer), a first conductive pattern layer ISU-CL1, a second sensing dielectric layer ISU-IL2 (or an intermediate dielectric layer), a second conductive pattern layer ISU-CL2, and a third sensing dielectric layer ISU-IL3 (or a cover dielectric layer). The first sensing dielectric layer ISU-IL1 may be directly disposed on the encapsulation layer 140.

In an embodiment of the disclosure, one or both of the first and third sensing dielectric layers ISU-IL1 and ISU-IL3 may be omitted. When the first sensing dielectric layer ISU-IL1 is omitted, the first conductive pattern layer ISU-CL1 may be disposed on an uppermost dielectric layer of the encapsulation layer 140. The third sensing dielectric layer ISU-IL3 may be replaced with an adhesion layer or a dielectric layer of the anti-reflector RPP disposed on the input sensing unit ISU.

The first conductive pattern layer ISU-CL1 may include first conductive patterns, and the second conductive pattern layer ISU-CL2 may include second conductive patterns. In the following description, the same reference numeral will be disposed to the first conductive pattern layer ISU-CL1 and the first conductive patterns, and the same reference numeral will be disposed to the second conductive pattern layer ISU-CL2 and the second conductive patterns.

The first conductive pattern layers (also referred to as first conductive patterns) ISU-CL1 and the second conductive pattern layers (also referred to as second conductive patterns) ISU-CL2 may each have a single-layered structure or a multi-layered structure in which layers are stacked along the third direction DR3. The conductive pattern having the multi-layered structure may include at least two selected from transparent conductive layers and metal layers. The conductive pattern having the multi-layered structure may include metal layers including different metals from each other. The transparent conductive layer may include indium tin oxide (“ITO”), indium zinc oxide (“IZO”), zinc oxide (ZnO), indium tin zinc oxide (“ITZO”), poly(3,4-ethylenedioxythiophene) (“PEDOT”), metal nano-wires, or graphene. The metal layer may include molybdenum, silver, titanium, copper, aluminum, or any alloys thereof. The following will describe in detail a stack structure of each of the first conductive pattern layer ISU-CL1 and the second conductive pattern layer ISU-CL2.

In the illustrated embodiment, each of the first to third sensing dielectric layers ISU-IL1 to ISU-IL3 may include an inorganic layer or an organic layer. In the illustrated embodiment, the first to third sensing dielectric layers ISU-IL1 to ISU-IL3 may include an inorganic layer. The inorganic layer may include silicon oxide, silicon nitride, or silicon oxynitride.

In an embodiment of the disclosure, at least one of the first to third sensing dielectric layers ISU-IL1 to ISU-IL3 may be an organic layer. In an embodiment, the third sensing dielectric layer ISU-IL3 may include an organic layer, for example. The organic layer may include at least one selected from an acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, and a perylene-based resin.

Referring to FIG. 4B, the input sensing unit ISU may include a sensing area ISU-DA and a non-sensing area ISU-NDA adjacent to the sensing area ISU-DA. The sensing area ISU-DA and the non-sensing area ISU-NDA may respectively correspond to the display area DA and the non-display area NDA depicted in FIG. 3.

The input sensing unit ISU may include first electrodes E1-1 to E1-7 and second electrodes E2-1 to E2-4 that are disposed on the sensing area ISU-DA and are insulated from each other while intersecting each other. The input sensing unit ISU may include signal lines SL disposed on the non-sensing area ISU-NDA. The signal lines SL may include first group signal lines SL1 electrically connected to the first electrodes E1-1 to E1-7 and second group signal lines SL2 electrically connected to the second electrodes E2-1 to E2-4. A combination of the first conductive patterns ISU-CL1 and the second conductive patterns ISU-CL2 discussed with reference to FIG. 4A may define the first electrodes E1-1 to E1-7, the second electrodes E2-1 to E2-4, the first group signal lines SL1, and the second group signal lines SL2.

The first electrodes E1-1 to E1-7 and the second electrodes E2-1 to E2-4 may each include a plurality of conductive lines that intersect each other. The plurality of conductive lines may define a plurality of openings, and the first electrodes E1-1 to E1-7 and the second electrodes E2-1 to E2-4 may each have a mesh shape. Each of the plurality of openings may be defined to correspond to an emission area of the display panel DP.

The first electrodes E1-1 to E1-7 or the second electrodes E2-1 to E2-4 may have a single unitary shape. In the illustrated embodiment, the first electrodes E1-1 to E1-7 are illustrated as a single unitary shape. The first electrodes E1-1 to E1-7 may include a sensing electrode SP1 and intermediate parts CP1. Portions of the second conductive patterns ISU-CL2 may correspond to the first electrodes E1-1 to E1-7.

Each of the second electrodes E2-1 to E2-4 may include sensing electrodes SP2 and bridge patterns (or connection patterns) CP2. Two neighboring sensing electrodes SP2 may be connected to two bridge patterns CP2 through a contact hole CH-I that penetrates the second sensing dielectric layer (refer to ISU-IL2 of FIG. 3). Portions of the second conductive patterns ISU-CL2 may correspond to the sensing electrodes SP2. Portions of the first conductive patterns ISU-CL1 may correspond to the bridge patterns CP2.

In the illustrated embodiment, it is explained that the bridge patterns CP2 are formed from the first conductive patterns ISU-CL1 shown in FIG. 4A, and that the first electrodes E1-1 to E1-7 and the sensing electrodes SP2 are formed from the second conductive patterns ISU-CL2 shown in FIG. 4A. The first electrodes E1-1 to E1-7 and the sensing electrodes SP2 may be formed from the first conductive patterns ISU-CL1 shown in FIG. 3, and the bridge patterns CP2 may be formed from the second conductive patterns ISU-CL2.

Ones of the first group signal lines SL1 and the second group signal lines SL2 may transfer a transmitting signal for detecting an external input from an external circuit, and others of the first group signal lines SL1 and the second group signal lines SL2 may provide an external circuit with a receiving signal that is a variation in capacitance between the first electrodes E1-1 to E1-7 and the second electrodes E2-1 to E2-4. The first group signal lines SL1 and the second group signal lines SL2 may be connected to a sensing pad PD, and may either receive a transmitting signal from the sensing pad PD transmitted from an external circuit or provide an external circuit through the sensing pad PD with a variation in capacitance between the first electrodes E1-1 to E1-7 and the second electrodes E2-1 to E2-4. When viewed in plan, the sensing pads PD may be disposed on a part that corresponds to a lower end of the second base area AA2 of the display panel DP. The sensing pads PD may be electrically connected through anisotropic conductive layers to the circuit board (refer to MB of FIG. 1B).

Portions of the second conductive patterns ISU-CL2 may correspond to the first group signal lines SL1 and the second group signal lines SL2. The first group signal lines SL1 and the second group signal lines SL2 may have a multi-layered structure, and may include a first-layered line formed from the first conductive patterns ISU-CL1 and a second-layered line formed from the second conductive patterns ISU-CL2. Although not shown, the first-layered line and the second-layered line may be connected through a contact hole that penetrates the second sensing dielectric layer (refer to ISU-IL2 of FIG. 4A).

Referring to FIGS. 3, 4A, and 4B, the display device DD in an embodiment may further include a dam structure DAM that overlaps the non-sensing area ISU-NDA. Although the dam structure DAM is a component included in the display panel DP in terms of arrangement, FIG. 4B depicts an arrangement relationship between the dam structure DAM and components included in the input sensing unit ISU for convenience of description. The dam structure DAM may be disposed on the base layer (refer to 110 of FIG. 2) of the display panel DP. As shown in FIG. 4B, the dam structure DAM may overlap the non-sensing area ISU-NDA and may not overlap the sensing area ISU-DA. The dam structure DAM may be disposed on the non-display area NDA and may surround the display area DA.

Referring to FIGS. 3 and 4B, each of the display panel DP and the input sensing unit ISU may include a first side SD1 that extends in the first direction DR1 and a second side SD2 that extends in the second direction DR2. In the illustrated embodiment, the first side SD1 may be a side that is disposed adjacent to the display pads DPD and the sensing pads PD, and the second side SD2 may be a side that is adjacent to the first side SD1 and extends in the second direction DR2 from the first side SD1.

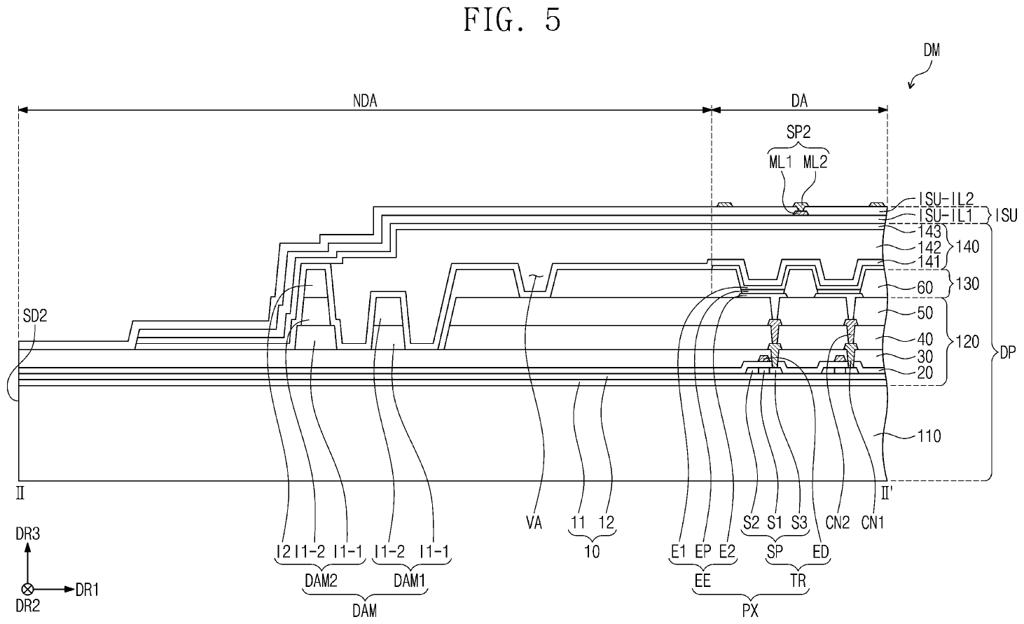

FIG. 5 illustrates a cross-sectional view showing an embodiment of a display module according to the disclosure. FIG. 5 shows a cross-section taken along line I-I′ of FIG. 4B.

Referring to FIG. 5, the display module DM may be configured such that the display panel DP and the input sensing unit ISU may be provided stacked.

The display panel DP may include a base layer 110 and a plurality of dielectric layers 10, 20, 30, 40, and 50 disposed on the base layer 110. The base layer 110 and the dielectric layers 10, 20, 30, 40, and 50 may be provided therebetween with components that constitute the pixel PX, the signal lines SGL1 to SGLm, DL1 to DLn, EL1 to ELm, CSL1, CSL2, and PL, and the scan driver circuit SDV. The circuit layer 120 may include the components that constitute the pixel PX, the signal lines SGL1 to SGLm, DL1 to DLn, EL1 to ELm, CSL1, CSL2, and PL, and the scan driver circuit SDV.

The base layer 110 may have insulation. The base layer 110 may have flexibility to bend. In an embodiment, the base layer 110 may be a dielectric polymer film, for example.

A first dielectric layer 10 may be disposed on the base layer 110. The first dielectric layer 10 may include a barrier layer 11 and a buffer layer 12. The barrier layer 11 may prevent introduction of foreign substances from outside. The barrier layer 11 may include one or both of a silicon oxide layer and a silicon nitride layer. Each of the silicon oxide layer and the silicon nitride layer may be provided in plural, and the silicon oxide layers and the silicon nitride layers may be alternately stacked with each other.

The buffer layer 12 may be disposed on the barrier layer 1. The buffer layer 12 may increase a bonding force between the base layer 110 and at least one selected from a semiconductor pattern and a conductive pattern. The buffer layer 12 may include one or both of a silicon oxide layer and a silicon nitride layer. The silicon oxide layer and the silicon nitride layer may be alternately stacked.

The pixels PX may be disposed on the first dielectric layer 10. FIGS. 4A and 4B depict by way of example a partial component of one pixel PX. The pixel PX may include a transistor TR and an emission element EE.

The transistor TR may include a semiconductor pattern SP and a gate ED. The semiconductor pattern SP may be disposed on the first dielectric layer 10. The semiconductor pattern SP may include a channel S1, a source S2, and a drain S3. The semiconductor pattern SP may include a silicon semiconductor, such as a monocrystalline silicon semiconductor, polycrystalline silicon semiconductor, or an amorphous silicon semiconductor. In an alternative embodiment, the semiconductor pattern SP may include an oxide semiconductor. In an embodiment of the disclosure, the semiconductor pattern SP may include or consist of any suitable material whatsoever as long as having semiconductor properties, but the disclosure is not limited to a particular embodiment.

The semiconductor pattern SP may have electrical properties that are different depending on whether the semiconductor pattern SP is doped or not. The semiconductor pattern SP may include a doped region and an undoped region. The doped region may be doped with n-type or p-type impurities. A p-type transistor may include a doped region implanted with p-type impurities. The doped region may have conductivity greater than that of the undoped region, and may substantially serve as an electrode or a signal line. The undoped region may substantially correspond to a channel (or active) of a transistor. In an embodiment, a portion of the semiconductor pattern SP may be the channel S1 of the transistor TR, another portion of the semiconductor pattern SP may be the source S2 or the drain S3 of the transistor TR, and still another portion of the semiconductor pattern SP may be a connection signal line (or connection electrode), for example.

A second dielectric layer 20 may be disposed on the first dielectric layer 10 to cover the semiconductor pattern SP. The second dielectric layer 20 may be disposed between the gate ED and the semiconductor pattern SP of the transistor TR. The second dielectric layer 20 may be one or more of an inorganic layer and an organic layer, and may have a single-layered or multi-layered structure. The second dielectric layer 20 may include at least one selected from aluminum oxide, titanium oxide, silicon oxide, silicon oxynitride, zirconium oxide, and hafnium oxide. In the illustrated embodiment, the second dielectric layer 20 may be a single-layered silicon oxide layer. An inorganic layer which will be discussed below may include at least one of the materials discussed above.

The gate ED may be disposed on the second dielectric layer 20. The gate ED may be a portion of a metal pattern. When viewed in plan, the gate ED may overlap the channel S1. The gate ED may serve as a mask in a process for doping the semiconductor pattern SP.

A third dielectric layer 30 may be disposed on the second dielectric layer 20 to cover the gate ED. The third dielectric layer 30 may be an inorganic layer, and may have a single-layered or multi-layered structure. In the illustrated embodiment, the third dielectric layer 30 may be a single-layered silicon oxide layer.

This, however, is not limited thereto, and the transistor TR may be configured such that the source S2 or the drain S3 may be an electrode independently formed from the semiconductor pattern SP. The source S2 and the drain S3 may contact the semiconductor pattern SP or may penetrate a dielectric layer to be coupled to the semiconductor pattern SP. The gate ED may be disposed below the semiconductor pattern SP. In an embodiment of the disclosure, the transistor TR may be formed having various forms, and the disclosure is not limited to a particular embodiment.

A fourth dielectric layer 40 may be disposed on the third dielectric layer 30. The fourth dielectric layer 40 may be an organic layer and may have a single-layered or multi-layered structure. In an embodiment, the fourth dielectric layer 40 may be a single-layered polyimide-based resin layer, for example. The disclosure, however, is not limited thereto, and the fourth dielectric layer 40 may include at least one selected from an acryl-based resin, a methacryl-based resin, polyisoprene, a vinyl-based resin, an epoxy-based resin, a urethane-based resin, a cellulose-based resin, a siloxane-based resin, a polyamide-based resin, and a perylene-based resin. An organic layer which will be discussed below may include at least one of the materials discussed above.

A first connection electrode CN1 may be disposed on the third dielectric layer 30, and a second connection electrode CN2 may be disposed on the fourth dielectric layer 40. The first connection electrode CN1 may penetrate the second dielectric layer 20 and the third dielectric layer 30 to come into electrical connection with the semiconductor pattern SP. The second connection electrode CN2 may penetrate the fourth dielectric layer 40 to come into electrical connection with the first connection electrode CN1.

One or both of the first and second connection electrodes CN1 and CN2 may be omitted. In an alternative embodiment, an additional connection electrode may further be disposed to connect the emission element EE to the transistor TR. An electrical connection between the emission element EE and the transistor TR may be variously changed depending on the number of dielectric layers disposed between the emission element EE and the transistor TR, but the disclosure is not limited to a particular embodiment.

A fifth dielectric layer 50 may be disposed on the fourth dielectric layer 40 to cover the second connection electrode CN2. The fifth dielectric layer 50 may be an organic or inorganic layer, and may have a single-layered or multi-layered structure. The plurality of dielectric layers 10, 20, 30, 40, and 50 and the transistor TR may be a component that corresponds to the circuit layer 120 discussed in FIG. 2. At least a portion of a top surface of each of the dielectric layers 10, 20, 30, 40, and 50 may have a flat surface parallel to a top surface of the base layer 110.

The emission element EE may be disposed on the fifth dielectric layer 50. The emission element EE may include a first electrode E1, an emission layer EP, and a second electrode E2. The first electrode E1 may be electrically connected to the transistor TR through the first connection electrode CN1 and the second connection electrode CN2.

A sixth dielectric layer 60 may be disposed on the fifth dielectric layer 50 to expose at least a portion of the first electrode E1. In the following description, the sixth dielectric layer 60 may be also referred to as a pixel definition layer. The pixel definition layer 60 may be an inorganic layer, an organic layer, or any combinations thereof, and may have a single-layered or multi-layered structure. In this description, the pixel definition layer 60 and the emission element EE may be a component that corresponds to the emission element layer 130 discussed in FIG. 2.

The emission layer EP may be disposed on the first electrode E1. The emission layer EP may provide light having a predetermined color. A patterned single-layered emission layer EP is illustrated in the illustrated embodiment, but the disclosure is not limited thereto. In an embodiment, the emission layer EP may have a multi-layered structure, for example. In addition, the emission layer EP may be provided in common on a plurality of pixels PX, while extending toward a top surface of the pixel definition layer 60.

The second electrode E2 may be disposed on the emission layer EP. Although not shown, an electron control layer (or electron control region) may be disposed between the second electrode E2 and the emission layer EP, and a hole control layer (or hole control region) may be disposed between the first electrode E1 and the emission layer EP.

In an embodiment of the disclosure, a via VA may be defined in the pixel definition layer 60. The via VA may be disposed on the non-display area NDA, and may be formed recessed in the third direction DR3 in the pixel definition layer 60. The via VA may prevent an overflow of the organic layer 142.

The encapsulation layer 140 may be disposed on the pixel definition layer 60 to cover the emission element EE. The encapsulation layer 140 may include at least one organic layer. The encapsulation layer 140 may include a plurality of inorganic layers and at least one organic layer disposed between the plurality of inorganic layers. In an embodiment, the encapsulation layer 140 may include a first inorganic layer 141, an organic layer 142, and a second inorganic layer 143.

The first inorganic layer 141 may be disposed on the second electrode E2. The organic layer 142 may be disposed on the first inorganic layer 141. The second inorganic layer 143 may be disposed on and may cover the organic layer 142. The first inorganic layer 141 and the second inorganic layer 143 may include a silicon nitride layer, a silicon oxynitride layer, or a silicon oxide layer. The first inorganic layer 141 and the second inorganic layer 143 may include a titanium oxide layer or an aluminum oxide layer, but the disclosure is not limited to a particular embodiment. The organic layer 142 may include an acryl-based organic layer or a silicon-based organic layer. Additionally or alternatively, the organic layer 142 may include a liquid monomer, but the disclosure is not limited to a particular embodiment. The first inorganic layer 141 and the second inorganic layer 143 may protect the emission element EE against moisture, oxygen, and/or foreign substances.

The display panel DP may further include the dam structure DAM disposed on the non-display area NDA. The dam structure DAM may be disposed on an outer region of the display module DM to prevent an overflow of the organic layer 142.

The dam structure DAM may be provided in plural. The dam structure DAM may include a first dam DAM1 and a second dam DAM2. The first dam DAM1 and the second dam DAM2 may be sequentially arranged along a direction away from the display area DA. In an embodiment, the second dam DAM2 may be disposed farther away than the first dam DAM1 from the display area DA or an emission element, and the first dam DAM1 may be disposed between the display area DA and a region where the second dam DAM2 is disposed, for example.

Each of the first and second dams DAM1 and DAM2 may include a plurality of layers. In an embodiment, the first dam DAM1 may include a 1-1^{st} layer I1-1 and a 1-2^{nd} layer I1-2, and the second dam DAM2 may include a 1-1^{st} layer I1-1, a 1-2^{nd} layer I1-2, and a second layer 12. The first dam DAM1 may have a height less than that of the second dam DAM2. The 1-1^{st} layer I1-1 and the 1-2^{nd} layer I1-2 may constitute a first layer and may respectively correspond to the fourth dielectric layer 40 and the fifth dielectric layer 50. In an embodiment, the 1-1^{st} layer I1-1 and the fourth dielectric layer 40 may include or consist of the same material in the same process, for example. The 1-2^{nd} layer I1-2 and the fifth dielectric layer 50 may include or consist of the same material in the same process. The second layer 12 may correspond to the pixel definition layer 60. The second layer 12 and the pixel definition layer 60 may include or consist of the same material in the same process. The first dam DAM1 may include the 1-1^{st} layer I1-1, the 1-2^{nd} layer I1-2, and a portion of the first inorganic layer 141 that covers top and lateral surfaces of the 1-1^{st} layer I1-1 and the 1-2^{nd} layer I1-2.

The second dam DAM2 may include the 2-1^{st} layer I1-1, the 2-2^{nd} layer I1-2, the second layer 12, and a portion of the first inorganic layer 141 that covers top and lateral surfaces of the 2-1^{st} layer I1-1, the 2-2^{nd} layer I1-2, and the second layer 12.

The input sensing unit ISU may be disposed on the display panel DP. The input sensing unit ISU may include a first conductive layer ML1, a second conductive layer ML2, a first sensing dielectric layer ISU-IL1, and a second sensing dielectric layer ISU-IL2. The second conductive layer ML2 may be disposed at a different layer from that of the first conductive layer ML1, and may be disposed on the second sensing dielectric layer ISU-IL2. The second sensing dielectric layer ISU-IL2 may be disposed on the first sensing dielectric layer ISU-IL1 to cover the first conductive layer ML1. Although not shown in FIG. 5, the second conductive layer ML2 may be provided thereon with the third sensing dielectric layer ISU-IL3 discussed in FIG. 4A.

One or both of the first and second conductive layers ML1 and ML2 may constitute a sensing electrode SP2. In the illustrated embodiment, the sensing electrode SP2 is illustrated to have a mesh-shaped pattern as discussed above and to include the first conductive layer ML1 and the second conductive layer ML2 coupled to the first conductive layer ML1. This, however, is an illustrative embodiment, and the sensing electrode SP2 may be a portion of one of the first and second conductive layers ML1 and ML2. In an alternative embodiment, the sensing electrode SP2 may have a single unitary pattern that overlaps a plurality of emission elements. In addition, one or both of the first and second conductive layers ML1 and ML2 may include transparent conductive oxide or opaque metal, but the disclosure is not limited to a particular embodiment.

Portions of the first and second conductive layers ML1 and ML2 may be signal lines (refer to SL of FIG. 4B). In the illustrated embodiment, the signal lines (refer to SL of FIG. 4B) are illustrated to include a plurality of layers disposed on the first sensing dielectric layer ISU-IL1 and the second sensing dielectric layer ISU-IL2, for example

The signal lines (refer to SL of FIG. 4B) may have a bi-layered structure including a first signal line disposed on the first sensing dielectric layer ISU-IL1 and a second signal line disposed on the second sensing dielectric layer ISU-IL2. However, at least a portion of the signal lines (refer to SL of FIG. 4B) may correspond to one of the first conductive layer ML1 and the second conductive layer ML2, but the disclosure is not limited to a particular embodiment. The first signal line and the second signal line may be partially connected to each other through a contact hole defined in the second sensing dielectric layer ISU-IL2.

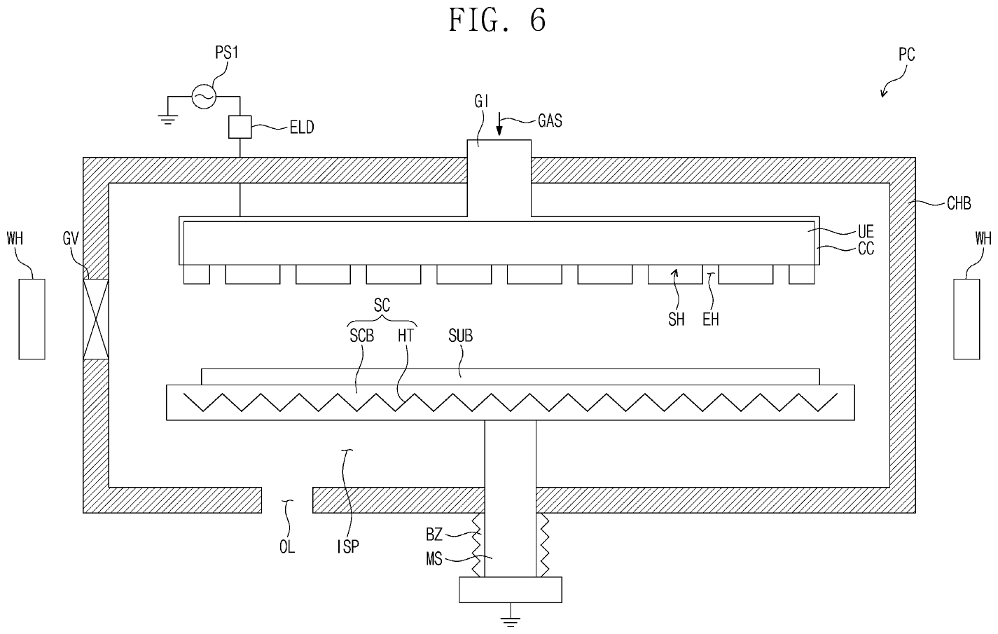

FIG. 6 illustrates a simplified diagram showing an embodiment of a deposition apparatus according to the disclosure.

Referring to FIG. 6, a deposition apparatus PC may deposit a thin layer on a substrate SUB by a plasma enhanced chemical vapor deposition (“PECVD”) method in which a chemical reaction of a process gas GAS is induced under a condition where a high-voltage energy is used to excite the process gas GAS into a plasma state.

The deposition apparatus PC may include a chamber CHB, a gate GV, an exhaust OL, an external heater WH, a substrate SUB, a bellows BZ, a shaft MS, a susceptor SC, a power unit PS1, a showerhead SH, an upper electrode UE, and a gas inlet GI. In this description, the deposition apparatus PC may include universal components other than those shown in FIG. 6, which should be understood by those having ordinary knowledge in the art.

The deposition apparatus PC may include the chamber CHB that provides an internal space ISP which is distinguished from an external region and in which a chemical reaction is executed. The chamber CHB may have, at one lateral surface, a gate GV through which the substrate SUB is loaded and unloaded and which opens and closes the chamber CHB. After the gate GV is opened, the substrate SUB may be introduced into the internal space ISP of the chamber CHB and may be placed on a top surface of the susceptor SC.

The external heater WH may be disposed adjacent to an external surface of the chamber CHB. The external heater WH may be disposed to prevent an internal temperature of the chamber CHB from being affected by an external temperature of the chamber CHB. The chamber CHB may have, at its bottom surface, the exhaust OL through which the process gas GAS is discharged.

At the bottom surface of the chamber CHB, the exhaust OL may be disposed adjacent to the gate GV.

In an embodiment of the disclosure, the substrate SUB may be a mother substrate including a plurality of display panels (refer to DP of FIG. 2). However, the substrate SUB may include only one display panel (refer to DP of FIG. 2), but the disclosure is not limited to a particular embodiment.

The upper electrode UE may be disposed above the substrate SUB while facing the substrate SUB. The upper electrode UE may include the gas inlet GI. A plurality of injection holes EH may be defined in the upper electrode UE. The upper electrode UE may include aluminum. The material of the upper electrode UE is not limited thereto but may be variously changed. In an embodiment, the upper electrode UE may include a stainless steel, for example.

The process gas GAS may be introduced through the gas inlet GI into the upper electrode UE. The introduced process gas GAS may be uniformly injected through the plurality of injection holes EH to a top surface of the substrate SUB. The process gas GAS may include a deposition gas which will be discussed below. The deposition gas may include silane (SiH₄), but may include other gases for deposition.

The power unit PS1 may be electrically connected to, and may supply a radio-frequency (“RF”) power to, the upper electrode UE and the showerhead SH. The power unit PS1 may be connected to a matcher ELD for impedance matching.

The upper electrode UE may be electrically connected to the power unit PS1. The upper electrode UE may supply energy desired for exciting the injected process gas GAS. The energy may form plasma from the process gas GAS injected through the plurality of injection holes EH. The plasmatized process gas GAS may be adsorbed on a surface of the substrate SUB, and then repeatedly diffused and detached to form a thin layer.

A conductive sheet CC may be disposed on a surface of the upper electrode UE. The conductive sheet CC may transfer a power from the power unit PS1 to the upper electrode UE. The conductive sheet CC may include a material having electrical conductivity and thermal conductivity.

The showerhead SH may be combined below the upper electrode UE to uniformly inject a gas toward the substrate SUB. The showerhead SH may have the plurality of injection holes EH defined therein, and a gas may be uniformly injected through the plurality of injection holes EH to the substrate SUB.

The susceptor SC may include a susceptor body SCB and a hot wire HT. The substrate SUB may be placed on one surface of the susceptor SC. The susceptor SC may support and heat the substrate SUB placed thereon. The susceptor SC may be supported by the shaft MS disposed below the susceptor SC. The shaft MS may be surrounded by the bellows BZ that envelops an outer circumference of the shaft MS. The bellows BZ may encapsulate and protect the shaft MS against external impact.

The susceptor SC may serve as an electrode opposite to the upper electrode UE that is a plasma electrode, and thus the susceptor SC and the upper electrode UE may face each other. The susceptor SC may be grounded through the shaft MS. In an embodiment, a current of the susceptor SC may be discharged through the shaft MS, for example.

After the substrate SUB is loaded on the top surface of the susceptor SC, when an RF power is applied to the upper electrode UE while the process gas GAS is applied through the showerhead SH to the substrate SUB, plasma may be created between the upper electrode UE and the susceptor SC, and the plasma may excite the process gas GAS. As molecules of the excited gas are deposited on the substrate SUB at a predetermined temperature, a thin layer may be formed on the substrate SUB.

The susceptor body SCB may be disposed (e.g., mounted) within the chamber CHB, and may have a plate shape that extends parallel to a plane defined by the first direction DR1 and the second direction DR2.

The susceptor SC may have therein the hot wire HT installed to control a temperature of the substrate SUB. The susceptor SC may have therein a path for supplying a backside gas, such as a helium gas, which effectively transfers the temperature of the susceptor SC to the substrate SUB. The susceptor SC may include metal. In an embodiment, the susceptor SC may include aluminum, for example.

The susceptor SC may serve as a substrate table which stably supports the substrate SUB during a deposition process, and the hot wire HT may generate heat to control the temperature of the substrate SUB.

The hot wire HT may be disposed within the susceptor body SCB. The hot wire HT may provide the substrate SUB with heat. In the procedure of thin-layer deposition, the hot wire HT may heat the substrate SUB to a temperature appropriate for deposition. Such temperature may facilitate diffusion of the plasmatized process gas GAS in the substrate SUB and may allow the plasmatized process gas GAS to favorably flow into a stable bonding structure.

Although FIG. 6 depicts an embodiment of the deposition apparatus PC in an embodiment of the disclosure, a deposition apparatus for fabricating the display panel DP of the disclosure is not limited to the deposition apparatus PC shown in drawing figures, and may be any other deposition apparatuses capable of performing the same function.

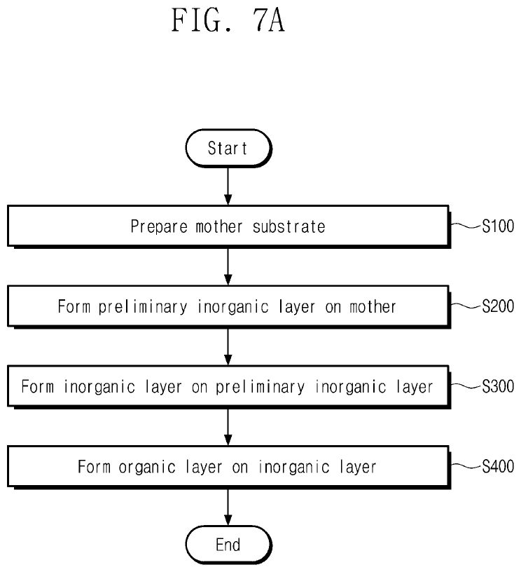

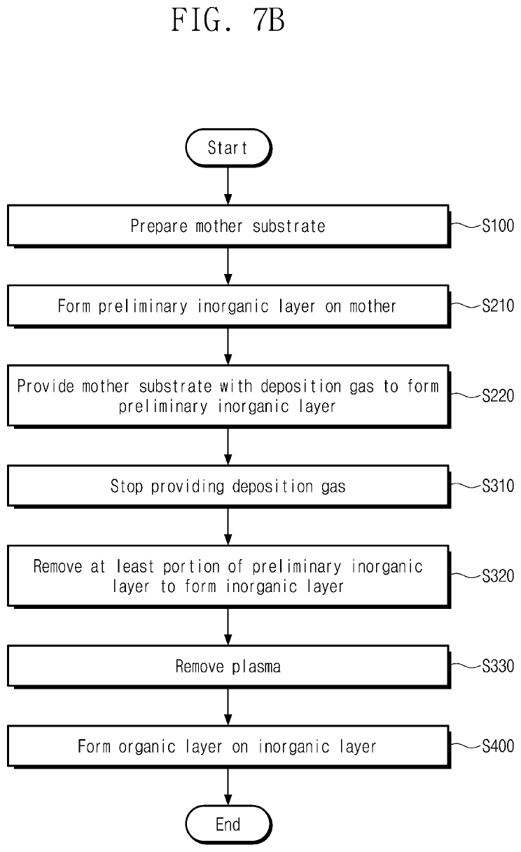

FIGS. 7A and 7B illustrate flow charts showing an embodiment of a method of fabricating a display panel according to the disclosure.

Referring to FIGS. 7A and 7B, a method of fabricating a display panel in an embodiment of the disclosure may include preparing a mother substrate (S100), forming a preliminary inorganic layer on the mother substrate (S200), forming an inorganic layer from the preliminary inorganic layer (S300), and forming an organic layer on the inorganic layer (S400).

In an embodiment, the mother substrate provided in the operation S100 may be a substrate that includes the display panel (refer to DP of FIG. 2) on which is formed an organic emission element including an anode, an emission layer, and a cathode on a display area, for example. In addition, the display panel (refer to DP of FIG. 2) of the mother substrate may include the first dam (refer to DAM1 of FIG. 5) spaced apart from an emission element and the second dam (refer to DAM2 of FIG. 5) farther away than the first dam (refer to DAM1 of FIG. 5) from the emission element.

In addition, as discussed above, the mother substrate may include a plurality of display panels (refer to DP of FIG. 2) or only one display panel (refer to DP of FIG. 2), but the disclosure is not limited to a particular embodiment.

The operation S200 may include providing the mother substrate with plasma (S210) and providing the mother substrate with a deposition gas to form the preliminary inorganic layer on the mother substrate (S220).

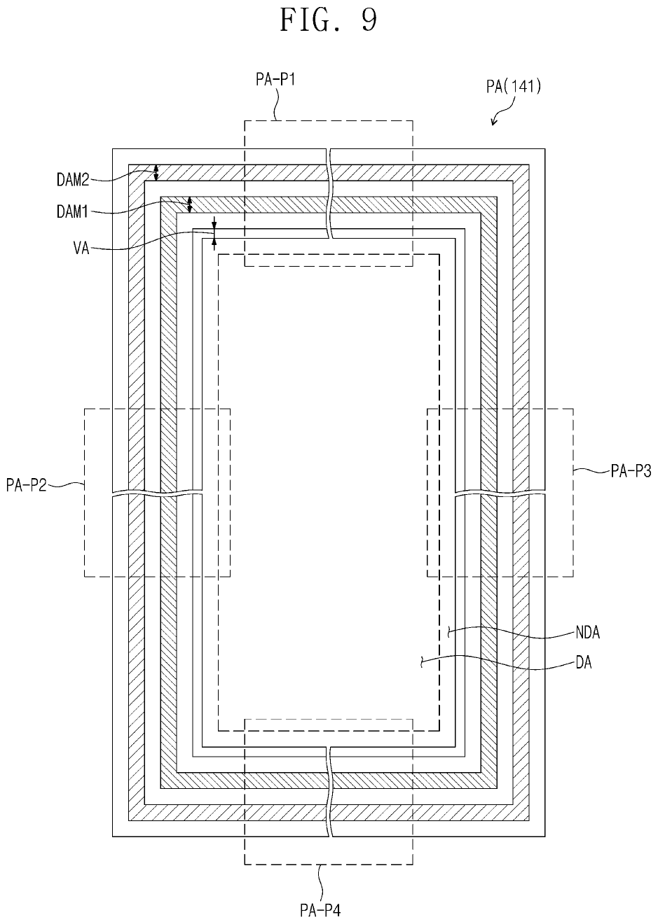

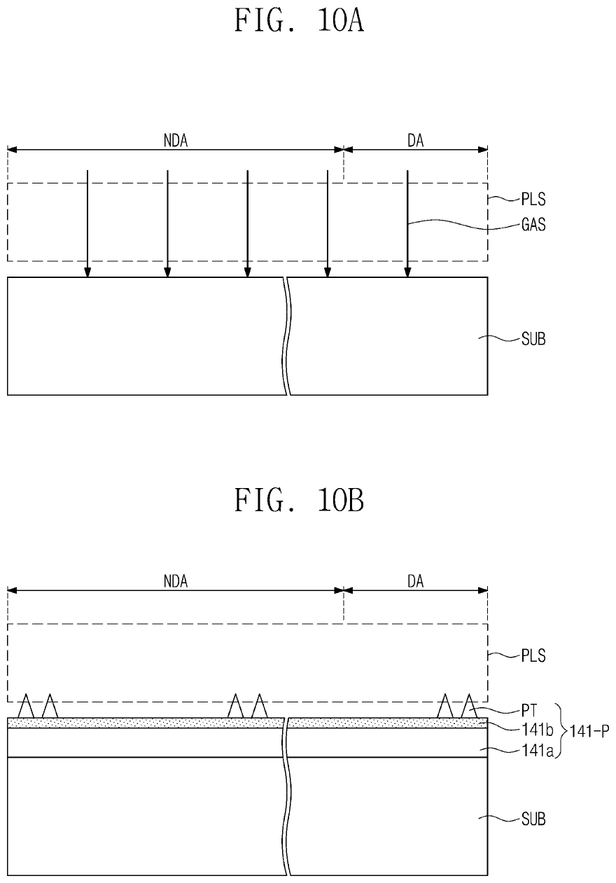

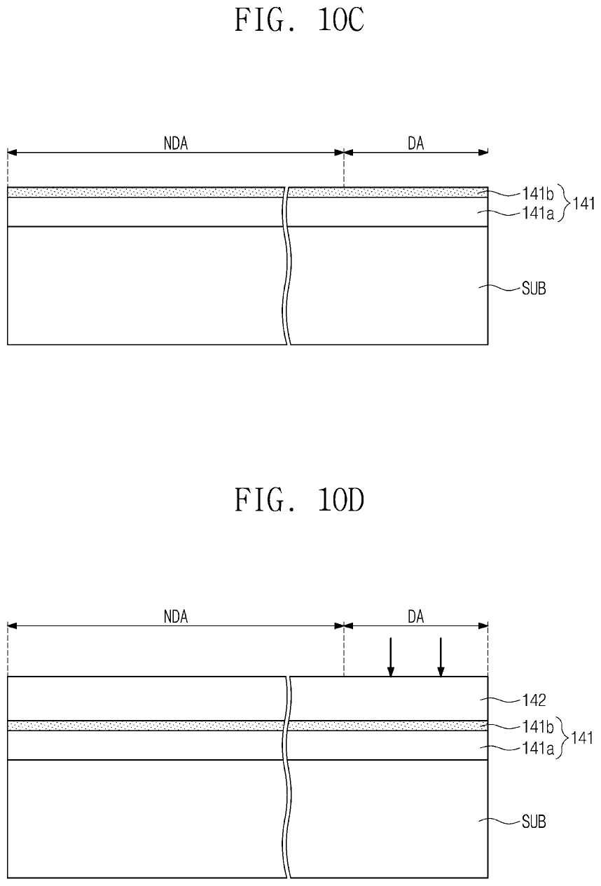

In an embodiment, referring to FIGS. 7A and 7B together with FIG. 10A which will be discussed below, plasma (refer to PLS of FIG. 10A) and a deposition gas (refer to GAS of FIG. 10A) may be concurrently provided on a substrate (refer to SUB of FIG. 10A) to form the preliminary inorganic layer that covers the substrate (refer to SUB of FIG. 10A), for example.

The mother substrate may be concurrently provided with the plasma and the deposition gas for a time desired for allowing a preliminary inorganic layer (refer to 141-P of FIG. 10B) to have an upper layer (refer to 141b of FIG. 10B) whose ratio of oxygen to silicon is in a range of about 1.5 to about 5. In an embodiment, the mother substrate may be concurrently provided with the plasma and the deposition gas for a predetermined time such that a ratio of oxygen atoms to silicon atoms in the upper layer (refer to 141b of FIG. 10B) may range from about 1.5 to about 5, for example.

The operation S300 may include stopping providing the deposition gas (S310), removing at least a portion of the preliminary inorganic layer to form the inorganic layer (S320), and removing plasma (S330).

In an embodiment, referring to FIGS. 7A and 7B together with FIG. 10B which will be discussed below, the removed at least a portion of the preliminary inorganic layer (refer to 141-P of FIG. 10B) may include a silicon pattern (refer to PT of FIG. 10B), and the silicon pattern (refer to PT of FIG. 10B) may be removed by plasma (refer to PLS of FIG. 10B), for example.

In an embodiment of the disclosure, after the operation S310, an operation of removing plasma (S330) may be performed after a predetermined time elapses. In an embodiment, the predetermined time may range from about 0.5 second to about 2 seconds, for example. In addition, the predetermined time may be a time desired for allowing the inorganic layer to have a surface roughness of about 4 nanometers (nm) and allowing the inorganic layer to have substantially the same surface roughness between a top surface of a portion that overlaps a display area and a top surface of a portion that overlaps a non-display area.

In the operation S400, an organic material including a liquid monomer may be injected onto the inorganic layer. The organic material may be injected onto the inorganic layer that overlaps the display area, and may also flow onto the inorganic layer that overlaps the non-display area.

In an embodiment of the disclosure, the inorganic layer may be provided thereon with the organic material which is injected onto the display area and has a fluidity capable of sufficiently extending between the first dam (refer to DAM1 of FIG. 5) and the second dam (DAM2 of FIG. 5). In an embodiment, the display panel (refer to DP of FIG. 5) in an embodiment of the disclosure may include an organic layer capable of sufficiently extending either between the first dam (refer to DAM1 of FIG. 5) and the second dam (DAM2 of FIG. 5) or to the first dam (refer to DAM1 of FIG. 5), for example, but the disclosure is not limited to a particular embodiment.

Before the operation S400, when a top surface of the inorganic layer does not have a desired surface roughness, plasma may be additionally provided to perform an additional process that allows the top surface of the inorganic layer to have a desired surface roughness. However, this process may be omitted, and the disclosure is not limited to a particular embodiment.

The deposition apparatus (refer to PC of FIG. 6) may be used in the operation S200 and the operation S300. However, it may be possible to use another deposition apparatus capable of performing the same function, but the disclosure is not limited to a particular embodiment.

When the deposition apparatus (refer to PC of FIG. 6) is used to form the inorganic layer, the mother substrate (refer to SUB of FIG. 6) may be provided in the internal space (refer to ISP of FIG. 6) of the chamber (refer to CHB of FIG. 6), and plasma (refer to PLS of FIG. 10A) and the deposition gas (refer to GAS of FIG. 6) may be provided in the internal space (refer to ISP of FIG. 6) of the chamber (refer to CHB of FIG. 6). In an embodiment, the deposition gas (refer to GAS of FIG. 6) may be a silane (SiH₄) gas.

Before the operation S400, when a top surface of the inorganic layer does not have a desired surface roughness, plasma may be additionally provided to perform an additional process that allows the top surface of the inorganic layer to have a desired surface roughness. However, this process may be omitted, and the disclosure is not limited to a particular embodiment.

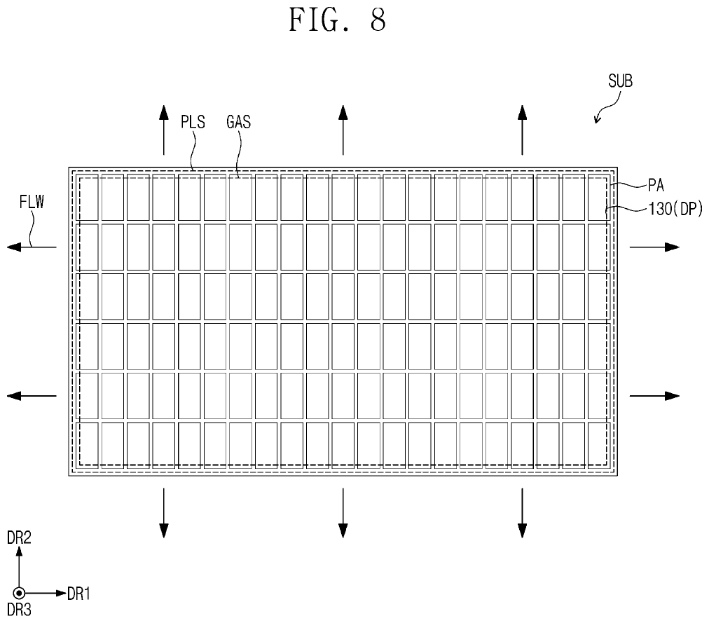

FIG. 8 illustrates a plan view showing an embodiment of a mother substrate SUB according to the disclosure.

In the following description, a mother substrate SUB may be the same as the substrate (refer to SUB of FIG. 6).

Referring to FIG. 8, the mother substrate SUB may define a plurality of partial areas PA. In an embodiment, the mother substrate SUB may include a plurality of partial areas PA, for example. Each of the plurality of partial areas PA may correspond to a portion of the display panel (refer to DP of FIG. 2) or a portion of the display module (refer to DM of FIG. 2). In an embodiment, the mother substrate SUB may include a portion of a plurality of display panels (refer to DP of FIG. 2) or a portion of a plurality of display modules (refer to DM of FIG. 2), for example.

As shown in drawing figures, in an embodiment of the disclosure, the mother substrate SUB may include partial areas PA that correspond to the display panel (refer to DP of FIG. 2) on which the emission element layer (refer to 130 of FIG. 2) is formed at top thereof.

The mother substrate SUB may be provided with plasma PLS and/or deposition gas GAS to form a preliminary inorganic layer (refer to 141-P of FIG. 10B) on the mother substrate SUB and to form an inorganic layer (refer to 141 of FIG. 10C) of the preliminary inorganic layer (refer to 141-P of FIG. 10B).

An inorganic layer (refer to 141 of FIG. 10C) which will be discussed below may correspond to the first inorganic layer (refer to 141 of FIG. 4) which is discussed above. In an embodiment, a predetermined process may be performed to form the first inorganic layer (refer to 141 of FIG. 4) from the preliminary inorganic layer (refer to 141-P of FIG. 10C), for example.

The plasma PLS may be provided to an entirety of the partial areas PA of the mother substrate SUB. In addition, the deposition gas GAS may also be provided to an entirety of the partial areas PA of the mother substrate SUB.

There may be a difference in range between the plasma PLS and the deposition gas GAS that are provided to the mother substrate SUB. As shown in drawing figures, although there is a difference on the mother substrate SUB between a region to which the deposition gas GAS is provided and a region to which the plasma PLS is provided, the both regions may be substantially the same as each other, but the disclosure is not limited to a particular embodiment.

The deposition gas GAS provided to the mother substrate SUB may move along a flow FLW from central to outer portions of the mother substrate SUB. Therefore, the deposition gas GAS may uniformly flow from the central to outer portions of the mother substrate SUB.

However, the flow FLW of the deposition gas GAS may be opposite to that shown in drawing figures, but the disclosure is not limited to a particular embodiment.

FIG. 9 illustrates a plan view partially showing an embodiment of a substrate according to the disclosure. In an embodiment, FIG. 9 is an enlarged view showing the partial area PA of the mother substrate SUB depicted in FIG. 8, for example.

FIG. 9 omits an illustration of the organic layer (refer to 142 of FIG. 5) of the display panel (refer to DP of FIG. 5) and its overlaying components.

Referring to FIG. 9, each of the partial areas PA of the substrate SUB in an embodiment of the disclosure may include a display area DA and a non-display area NDA.

As discussed in FIGS. 2 to 4, the pixel (refer to PX of FIG. 3) including an emission element may be disposed on the display area DA, and the via VA, the first dam DAM1, and the second dam DAM2 may be disposed on the non-display area NDA.

In an embodiment, an organic material may be injected to the display area DA, and the organic material injected to the display area DA may flow toward the non-display area NDA, for example. The injected organic material and the flowed organic material may form the organic layer (refer to 142 of FIG. 5). The organic material may also be injected to a portion of the non-display area NDA, but the disclosure is not limited to a particular embodiment.

For convenience of description, FIG. 9 depicts that the display area DA has a smaller area than that of the non-display area NDA, but actually the display area DA may have a larger area than that of the non-display area NDA. A difference in width (or size) between the display area DA and the non-display area NDA is not limited to that shown in FIG. 9, but the difference in width (or size) may be depicted as shown in FIGS. 1B and 3.

In an embodiment, the display area DA of FIG. 9 may correspond to the display area DA of FIG. 3, and the non-display area NDA of FIG. 9 may correspond to the non-display area NDA of FIG. 3, for example.

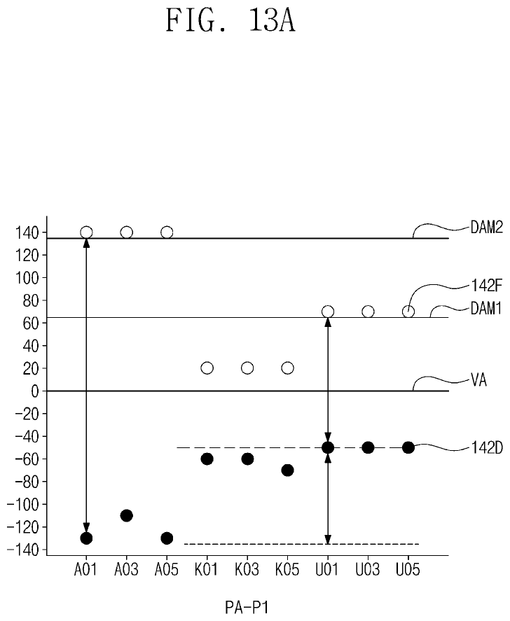

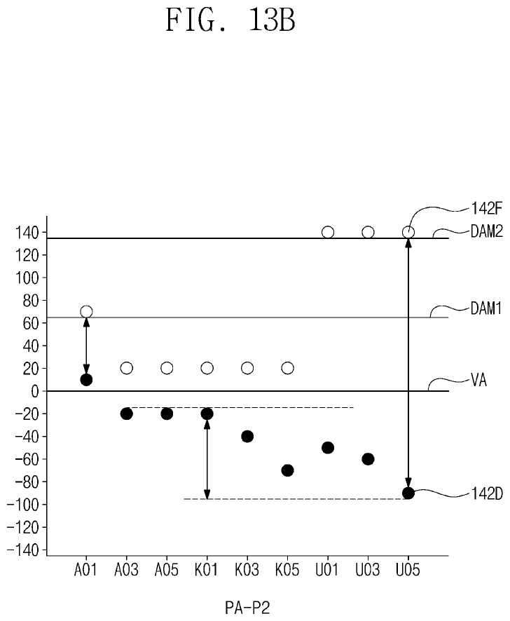

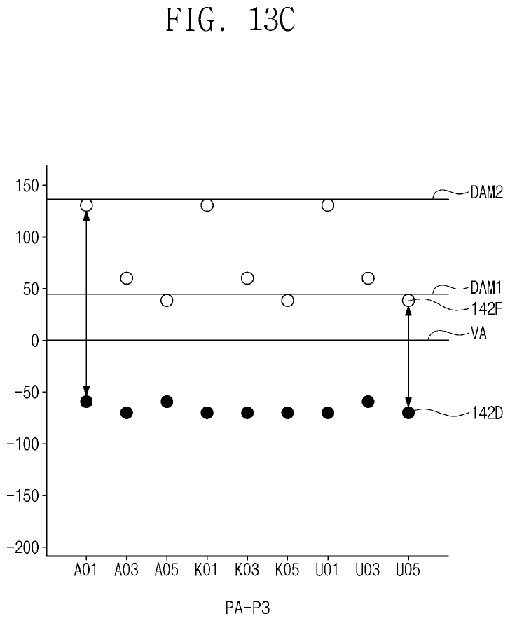

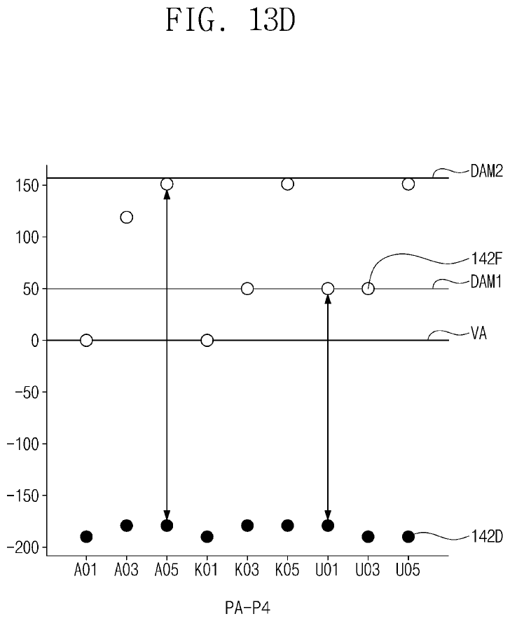

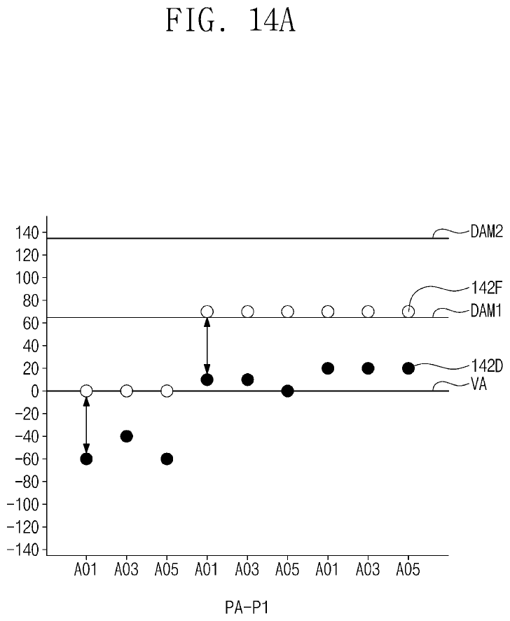

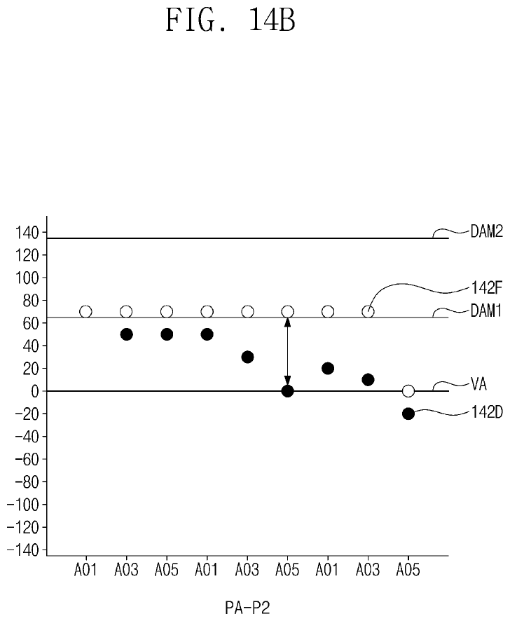

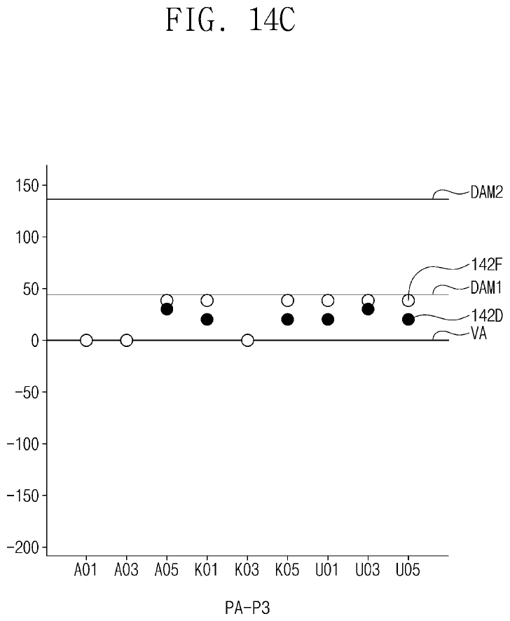

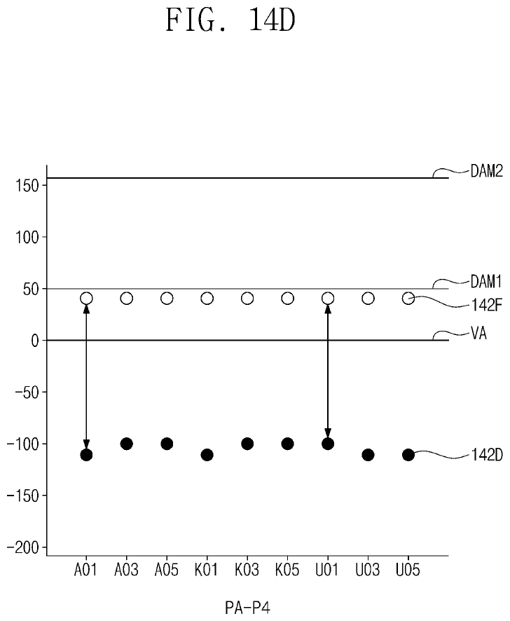

The following FIGS. 13A to 13D will describe the degree of dispersion of an organic material on sections PA-P1, PA-P2, PA-P3, and PA-P4 according to an injection of the organic material in a comparative embodiment of the disclosure. In addition, the following FIGS. 14A to 14D will describe the degree of dispersion of an organic material on sections PA-P1, PA-P2, PA-P3, and PA-P4 according to an injection of the organic material in an experimental embodiment of the disclosure.

FIGS. 10A to 10D illustrate cross-sectional views showing an embodiment of some operations of a method of fabricating a display panel according to the disclosure.

The following FIGS. 10A to 10D will describe in detail a stack structure of a display panel according to each operation of the display panel fabrication method discussed in FIGS. 7A and 7B.

Referring to FIG. 10A, in an embodiment of the disclosure, the mother substrate SUB may be provided with plasma and deposition gas to form a preliminary inorganic layer (refer to 141-P of FIG. 10B) on the mother substrate SUB.

In FIG. 10A and its following drawing figures, the mother substrate SUB may be in a state where in the display panel (refer to DP of FIG. 2) an upper layer (e.g., an uppermost layer) 141b is the emission element layer (refer to 130 of FIG. 2) and the encapsulation layer (refer to 140 of FIG. 2) is omitted.

As discussed in FIG. 8A, the deposition apparatus (refer to PC of FIG. 6) may be used to provide the mother substrate SUB with the plasma PLS and the deposition gas GAS. The plasma PLS and the deposition gas GAS provided to the mother substrate SUB may form the preliminary inorganic layer (refer to 141-P of FIG. 10B) on the mother substrate SUB.

An oxygen atom and a silicon atom may be included in the preliminary inorganic layer (refer to 141-P of FIG. 10B) formed from the plasma PLS and the deposition gas GAS that are provided to the mother substrate SUB.

Referring to FIGS. 10A and 10B, in an embodiment of the disclosure, the preliminary inorganic layer 141-P may be formed on a top surface of the mother substrate SUB. The preliminary inorganic layer 141-P may include an oxygen atom and a silicon atom.

The preliminary inorganic layer 141-P may include a lower layer 141a and an upper layer 141b. The lower layer 141a may be disposed on the mother substrate SUB, and the upper layer 141b may be disposed on the lower layer 141a. In an embodiment, the lower layer 141a may cover the top surface of the mother substrate SUB, and the upper layer 141b may cover a top surface of the lower layer 141a, for example.

In an embodiment of the disclosure, a ratio of oxygen atoms to silicon atoms may be greater in the upper layer 141b than in the lower layer 141a.

In an embodiment of the disclosure, the ratio of oxygen atoms to silicon atoms in the upper layer 141b may range from about 1.5 to about 5. In an embodiment, in an operation of forming the preliminary inorganic layer 141-P, the mother substrate SUB may be provided with both of the plasma PLS and the deposition gas GAS for a predetermined time to form the upper layer 141b whose ratio of oxygen atoms to silicon atoms is in a range of about 1.5 to about 5, for example.

The preliminary inorganic layer 141-P may include a silicon pattern PT. The silicon pattern PT may include or consist of only silicon atoms, but alternatively may include other atoms.

The silicon pattern PT may be disposed on the upper layer 141b. The silicon pattern PT may be disposed on one or both of the display area DA and the non-display area NDA, and the silicon patterns PT formed on different areas may have their shapes different from each other.

In this stage, the deposition gas GAS may be no longer provided to the mother substrate SUB, and the plasma PLS may be continuously provided to the mother substrate SUB. The plasma PLS continuously provided to the mother substrate SUB may remove at least a portion of the preliminary inorganic layer 141-P. The portion removed from the preliminary inorganic layer 141-P may include the silicon pattern PT. In an embodiment, at least a portion of the silicon pattern PT may be removed with the plasma PLS, for example.

Referring to FIGS. 10B and 10C, in an embodiment of the disclosure, the plasma PLS may remove the silicon pattern PT of the preliminary inorganic layer 141-P such that an inorganic layer 141 may be formed from the preliminary inorganic layer 141-P.

In the inorganic layer 141, the inorganic layer 141 that overlaps the display area DA may have a top surface whose surface roughness is substantially the same as that of a top surface of the inorganic layer 141 that overlaps the non-display area NDA. Although not shown in drawing figures, an entirety of the top surface of the inorganic layer 141 that overlaps the display area DA may have a surface roughness substantially the same as that of an entirety of the top surface of the inorganic layer 141 that overlaps the non-display area NDA.

In an embodiment of the disclosure, the top surface of the inorganic layer 141 may have a surface roughness equal to or less than about 4 nm. In an embodiment, a surface roughness equal to or less than 4 nm may be given to both the top surface of the inorganic layer 141 that overlaps the display area DA and the top surface of the inorganic layer 141 that overlaps the non-display area NDA, for example.

In an embodiment, in an operation of forming the inorganic layer 141 from the preliminary inorganic layer 141-P, the process gas GAS may be no longer provided to the mother substrate SUB and then the mother substrate SUB may be continuously provided with the plasma PLS for a predetermined time to allow a portion or entirety of the inorganic layer 141 that overlaps the display area DA to have a top surface whose surface roughness is substantially the same as that of a top surface of a portion or entirety of the inorganic layer 141 that overlaps the non-display area NDA, for example.

In an alternative embodiment, in an operation of forming the inorganic layer 141 from the preliminary inorganic layer 141-P, the process gas GAS may be no longer provided to the mother substrate SUB and then the mother substrate SUB may be continuously provided with the plasma PLS for a predetermined time to allow the inorganic layer 141 to have a top surface whose surface roughness is in a range equal to or less than about 4 nm.

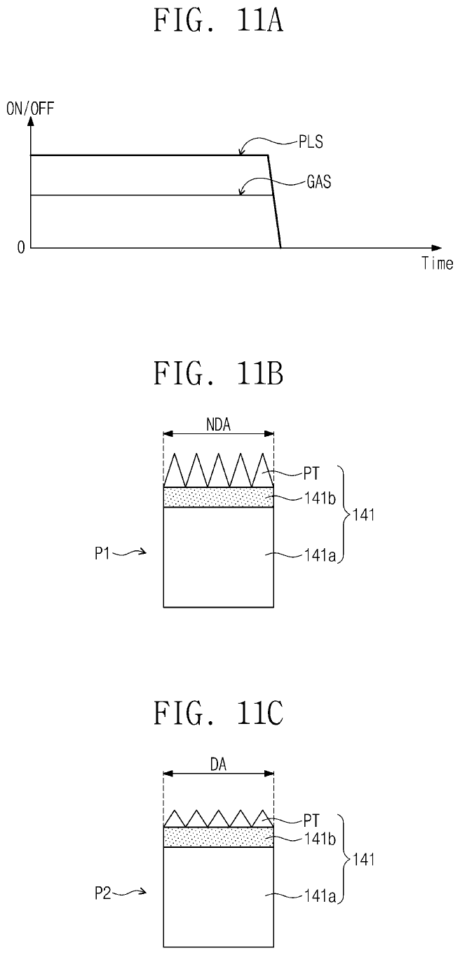

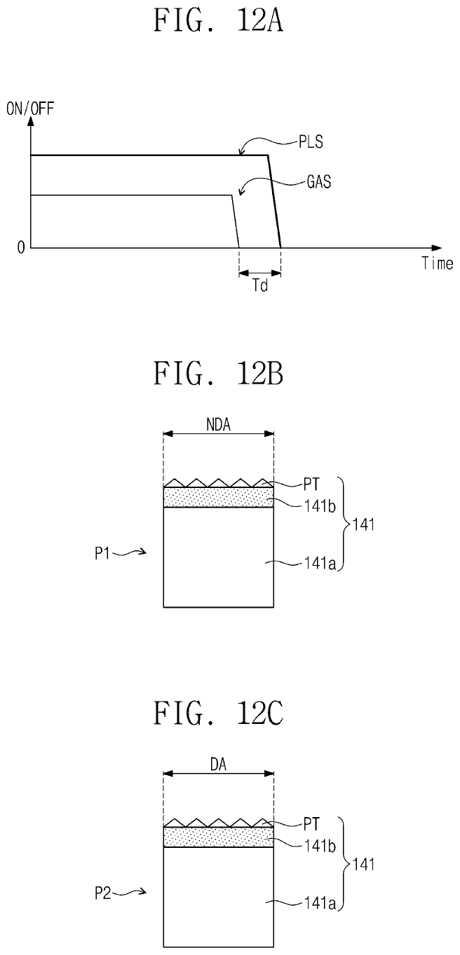

Although FIGS. 10A to 10C depict the case where the plasma PLS is caused to remove an entirety of the silicon pattern PT, a portion of the silicon pattern PT may remain on the upper layer 141b. With reference to FIGS. 11A to 11C and 12A to 12C, the following will describe in detail the case where a portion of the silicon pattern PT remains on the upper layer 141b.

Referring to FIG. 10D, in an embodiment of the disclosure, an organic layer 142 may be provided on the inorganic layer 141. In an embodiment, the organic layer 142 may be formed to cover a top surface of the inorganic layer 141, for example.

In an embodiment of the disclosure, as discussed above, an organic material may be injected onto the inorganic layer 141 on the mother substrate SUB that overlaps the display area DA, thereby forming the organic layer 142 that covers the top surface of the inorganic layer 141. In this stage, the organic material injected onto the inorganic layer 141 that overlaps the display area DA may have a fluidity, and thus may extend to the non-display area NDA to form the organic layer 142.

The organic layer 142 may be formed on the top surface of the inorganic layer 141 in a screen printing process other than that discussed above, and the disclosure is not limited to a particular embodiment.

FIGS. 11A to 11C illustrates diagrams showing an embodiment of a comparative embodiment of a display panel according to the disclosure. In an embodiment, the comparative embodiment of FIGS. 11A to 11C may show a surface roughness of an inorganic layer that overlaps a non-display area and a surface roughness of an inorganic layer that overlaps a display area, in a case where a removal of plasma and a supply stop of deposition gas are coincident with each other, for example.

Referring to FIGS. 11A to 11C, the comparative embodiment of FIG. 11A may be an example where removal of the plasma PLS is performed at the same time when supply of the deposition gas GAS is interrupted.

As shown in the graph, a substrate may be provided with the deposition gas GAS and the plasma PLS at the same time, and a time point of removal of the plasma PLS may be substantially the same as that of supply stop of the deposition gas GAS.

In this case, because the plasma PLS is removed simultaneously with the supply stop of the deposition gas GAS, the plasma PLS may not remove the silicon pattern (refer to PT of FIG. 10B) disposed on the preliminary inorganic layer (refer to 141-P of FIG. 10B). Therefore, the silicon pattern PT may remain on the inorganic layer 141.

Referring to FIG. 11B, it is illustrated a first part P1 or a portion of the inorganic layer 141 that overlaps the non-display area NDA in a case where the time point of removal of the plasma PLS is the same as that of supply stop of the deposition gas GAS according to the comparative embodiment of FIG. 11A.

The silicon pattern PT may remain on the inorganic layer 141, and the remaining silicon pattern PT may cause the inorganic layer 141 to have a top surface whose surface roughness is greater than about 4 nm. In an embodiment, in the comparative embodiment, the inorganic layer 141 that overlaps the non-display area NDA may have a top surface whose surface roughness is about 20 nm, for example.

Referring to FIG. 11C, it is illustrated a second part P2 or another portion of the inorganic layer 141 that overlaps the display area DA in a case where the time point of removal of the plasma PLS is the same as that of supply stop of the deposition gas GAS according to the comparative embodiment of FIG. 11A.

In the comparative embodiment, the inorganic layer 141 that overlaps the display area DA may have a top surface whose surface roughness is about 12 nm.

FIGS. 12A to 12C illustrate diagrams showing an experimental embodiment of a display panel according to the disclosure. In an embodiment, the experimental embodiment of FIGS. 12A to 12C may show a case where supply of the deposition gas GAS is interrupted and thereafter removal of the plasma PLS is performed, for example.

Referring to FIGS. 12A to 12C, the experimental embodiment of FIG. 12A may be an example where a time point of removal of the plasma PLS is performed at a time different from that for supply stop of the deposition gas GAS.

As shown in the graph, the supply stop of the deposition gas GAS may be followed by the removal of the plasma PLS. In an embodiment, after the supply stop of the deposition gas GAS, the plasma PLS may be removed after a predetermined time elapses, and there may be a time difference between the supply stop of the deposition gas GAS to a substrate and the removal of the plasma PLS provided to the substrate, for example. In an embodiment, the supply stop of the deposition gas GAS may be performed before the removal of the plasma PLS, and a time difference Td may be provided between a time point of the removal of the plasma PLS provided to the substrate and a time point of the supply stop of the deposition gas GAS, for example.

The plasma PLS may maintain during the time difference Td even after the supply stop of the deposition gas GAS, and thus the plasma PLS may be used to remove the silicon pattern (refer to PT of FIG. 10B) of the preliminary inorganic layer (refer to 141-P of FIG. 10B).

In an embodiment of the disclosure, the time difference Td may range from about 0.5 second to about 2.0 seconds.

When the time difference Td is less than about 0.5 second, the plasma PLS provided to the substrate may not desirably remove the silicon pattern (refer to PT of FIG. 10B) of the preliminary inorganic layer (refer to 141-P of FIG. 10B), and thus a significant difference may be provided between a surface roughness of the inorganic layer 141 that overlaps the display area DA and a surface roughness of the inorganic layer 141 that overlaps the non-display area NDA, which surface roughness is greater than about 4 nm. In an alternative embodiment, when the time difference Td is greater than about 2 seconds, a portion of the upper layer (refer to 141b of FIG. 10B) of the preliminary inorganic layer (refer to 141-P of FIG. 10B) may be removed together with the silicon pattern (refer to PT of FIG. 10B). When a portion of the upper layer 141b is removed, an organic material may have reduced properties of fluidity or reflow such that the organic layer (refer to 142 of FIG. 10D) may not uniformly cover the top surface of the inorganic layer 141.

FIG. 12B illustrates a first part P1 or a portion of the inorganic layer 141 that overlaps the non-display area NDA in a case where the plasma PLS is removed after an elapse of about 0.5 second to about 2.0 seconds after the supply stop of the deposition gas GAS according to the experimental embodiment of FIG. 12A.

In this case, the silicon pattern PT may remain on the inorganic layer 141, and the remaining silicon pattern PT may cause the inorganic layer 141 to have a top surface whose surface roughness is about 4 nm.

In comparison with the first part P1 of FIG. 11B whose surface roughness is about 20 nm, the first part P1 of FIG. 12B may have a surface roughness of about 4 nm.

FIG. 12C illustrates a second part P2 or another portion of the inorganic layer 141 that overlaps the display area DA in a case where the plasma PLS is removed after an elapse of about 0.5 second to about 2.0 seconds after the supply stop of the deposition gas GAS according to the experimental embodiment of FIG. 12A.

In this case, the silicon pattern PT may cause the inorganic layer 141 to have a top surface whose surface roughness is about 4 nm.

In comparison with the second part P2 of FIG. 11C whose surface roughness is about 12 nm, the second part P2 of FIG. 12C may have a surface roughness of about 4 nm.

When the inorganic layer 141 has a top surface whose surface roughness is uniform, an organic material may be uniformly dispersed on the inorganic layer 141, and an increased accuracy may be given to the organic layer (refer to 142 of FIG. 10D) that covers the top surface of the inorganic layer 141.

FIGS. 13A to 13D illustrate graphs showing the degree of dispersion of an organic material in a display panel according to a comparative embodiment of the disclosure.

In an embodiment, FIGS. 13A to 13D show the degree of a flowed organic material 142F in the comparative embodiment of FIGS. 11A to 11C, for example.

An organic material 142D may be coated on the inorganic layer (refer to 141 of FIG. 10D) on the display area (refer to DA of FIG. 10D), and as the organic material 142D coated on the display area (refer to DA of FIG. 10D) has fluidity, the organic material 142D may flow toward the non-display area (refer to NDA of FIG. 10D). The flowed organic material 142F may be disposed on the display area (refer to DA of FIG. 10D) or the non-display area (refer to NDA of FIG. 10D).

Referring to FIG. 13A, it is illustrated the degree of dispersion of the coated organic material 142D and the flowed organic material 142F on the section PA-P1 of FIG. 9 according to a comparative embodiment of the disclosure.

In FIG. 13A, the organic material 142D coated on the inorganic layer (refer to 141 of FIG. 10D) may flow toward the via VA and the first dam DAM1, and may flow across the first dam DAM1 and over the second dam DAM2. When an organic material flows as mentioned above, the first dam DAM1 and the second dam DAM2 may not prevent an overflow of the organic layer (refer to 142 of FIG. 10D), and may not block an introduction path of air and moisture in the display panel DP.

Referring to FIG. 13B, it is illustrated the degree of dispersion of the coated organic material 142D and the flowed organic material 142F on the section PA-P2 of FIG. 9 according to a comparative embodiment of the disclosure.

Likewise FIG. 13A, in FIG. 13B, the organic material 142D coated on the inorganic layer (refer to 141 of FIG. 10D) may flow across the via VA and the first dam DAM1 and over the second dam DAM2.

FIG. 13C illustrates the degree of dispersion of the coated organic material 142D and the flowed organic material 142F on the section PA-P3 of FIG. 9 according to a comparative embodiment of the disclosure, and FIG. 13D illustrates the degree of dispersion of the coated organic material 142D and the flowed organic material 142F on the section PA-P4 of FIG. 9 according to a comparative embodiment of the disclosure.

Referring to FIGS. 13C and 13D, unlike FIGS. 13A and 13B, the organic material 142D coated on the inorganic layer (refer to 141 of FIG. 10D) may flow across the via VA and the first dam DAM1 to the second dam DAM2.

FIGS. 14A to 14D illustrate graphs showing the degree of dispersion of an organic material in a display panel according to an experimental embodiment of the disclosure.

In an embodiment, FIGS. 14A to 14D show the degree of an organic material in the experimental embodiment of FIGS. 12A to 12C, for example.

As discussed above, the organic material 142D may be coated on the inorganic layer (refer to 141 of FIG. 10D) on the display area (refer to DA of FIG. 10D), and as the organic material 142D coated on the display area (refer to DA of FIG. 10D) has fluidity, the organic material 142D may flow toward the non-display area (refer to NDA of FIG. 10D).

Referring to FIG. 14A, it is illustrated the degree of dispersion of the coated organic material 142D and the flowed organic material 142F on the section PA-P1 of FIG. 9 according to the disclosure.

In FIG. 14A, the organic material 142D coated on the inorganic layer (refer to 141 of FIG. 10D) may flow across the via VA and the first dam DAM1, but may not flow to the second dam DAM2. In comparison with FIG. 13A, the first dam DAM1 and the second dam DAM2 may prevent an overflow of the organic layer (refer to 142 of FIG. 10D), and may block an introduction path of air and moisture in the display panel DP.

In addition, because a deviation in the degree of dispersion of a fluid material is less in an embodiment of the disclosure than in a comparative embodiment of the disclosure, it may be possible to uniformly disperse the organic materials 142D and 142F on the inorganic layer (refer to 141 of FIG. 10D) and to increase accuracy of the organic layer (refer to 142 of FIG. 10D) that covers the top surface of the inorganic layer (refer to 141 of FIG. 10D).

Referring to FIG. 14B, it is illustrated the degree of dispersion of the coated organic material 142D and the flowed organic material 142F on the section PA-P2 of FIG. 9 according to the disclosure.

Likewise FIG. 14A, in FIG. 14B, the organic material 142D coated on the inorganic layer (refer to 141 of FIG. 10D) may flow to the via VA and the first dam DAM1, but may not flow to the second dam DAM2.

In comparison with the comparative embodiment of FIG. 13B, the experimental embodiment of the disclosure may prevent the organic layer (refer to 142 of FIG. 10D) from overflowing the first dam DAM1 and the second dam DAM2, and may allow the organic materials 142D and 142F to uniformly disperse on the inorganic layer (refer to 141 of FIG. 10D).

FIG. 14C illustrates the degree of dispersion of the coated organic material 142D and the flowed organic material 142F on the section PA-P3 of FIG. 9 in an embodiment of the disclosure, and FIG. 13D illustrates the degree of dispersion of the coated organic material 142D and the flowed organic material 142F on the section PA-P4 of FIG. 9 according to the disclosure.

Referring to FIGS. 14C and 14D, in an experimental embodiment of the disclosure unlike the comparative embodiment of FIGS. 13C and 13D, the organic material 142D coated on the inorganic layer (refer to 141 of FIG. 10D) may flow across the via VA to the first dam DAM1, but may not flow to the second dam DAM2.

In an embodiment, when the plasma (refer to PLS of FIG. 12A) is removed after an elapse of about 0.5 second to about 2.0 seconds after the supply stop of the deposition gas (refer to GAS of FIG. 12A) according to an experimental embodiment of the disclosure, the inorganic layer (refer to 141 of FIG. 10D) may have a top surface whose surface roughness is about 4 nm, with the result that the organic material 142D coated on the inorganic layer (refer to 141 of FIG. 10D) may not flow to the second dam DAM2 and the organic materials 142D and 142F may be uniformly dispersed on the inorganic layer (refer to 141 of FIG. 10D). Therefore, an overflow of the organic layer (refer to 142 of FIG. 10D) may be prevented to block an introduction path of air and moisture in the display panel DP, and the organic layer (refer to 142 of FIG. 10D) covering the top surface of the inorganic layer (refer to 141 of FIG. 10D) may have increased accuracy.

In a display panel and its fabrication method in an embodiment of the disclosure, an inorganic layer may have a uniform surface roughness.

In a display panel and its fabrication method in an embodiment of the disclosure, the organic material may be uniformly dispersed on an inorganic layer.

In a display panel and its fabrication method in an embodiment of the disclosure, the organic layer covering the inorganic layer may have increased accuracy.

In a display panel and its fabrication method in an embodiment of the disclosure, an additional process on a surface of the inorganic layer may be unnecessary to secure economic efficiency and mass production.

Although the embodiments have been described with reference to a number of illustrative examples thereof, it will be understood by those of ordinary skill in the art that various changes in form and details may be made without departing from the spirit and scope of the disclosure as set forth in the following claims. Thus, the technical scope of the disclosure is not limited by the embodiments and examples described above, but by the following claims.

What is claimed is:

1. A display panel, comprising:
a base layer which includes a display area and a non-display area adjacent to the display area;
a plurality of emission elements on the display area; and
an encapsulation layer which includes an organic layer and an inorganic layer in contact with a bottom surface of the organic layer, the organic layer being on the plurality of emission elements, and the inorganic layer including an oxygen atom and a silicon atom,
wherein, in the inorganic layer, a top surface of a portion which overlaps the display area and a top surface of a portion which overlaps the non-display area have a substantially identical surface roughness.

2. The display panel of claim 1, wherein the inorganic layer includes:
a lower layer; and
an upper layer on the lower layer,
wherein a ratio of the oxygen atom to the silicon atom in the upper layer is greater than a ratio of the oxygen atom to the silicon atom in the lower layer.

3. The display panel of claim 1, further comprising:
a first dam spaced apart from the plurality of emission elements; and
a second dam farther away than the first dam from the plurality of emission elements,
wherein the organic layer extends between the first dam and the second dam.

4. The display panel of claim 1, wherein the substantially identical surface roughness equals to about 4 nanometers.

5. The display panel of claim 2, wherein the ratio of the oxygen atom to the silicon atom in the upper layer is in a range of about 1.5 to about 5.

6. A method of fabricating a display panel, the method comprising:
providing a mother substrate on which is formed an organic emission element which includes an anode, an emission layer, and a cathode on a display area;
providing the mother substrate with plasma;
providing the display area with a deposition gas to form a preliminary inorganic layer;
stopping providing the deposition gas;
removing at least a portion of the preliminary inorganic layer to form an inorganic layer; and
removing the plasma,
wherein the at least a portion of the preliminary inorganic layer is removed with the plasma.

7. The method of claim 6, wherein removing the plasma is performed after an elapse of a predetermined time duration from the supply stop of the deposition gas,
wherein the predetermined time is a time taken until the inorganic layer has a surface roughness of about 4 nanometers.

8. The method of claim 6, wherein removing the plasma is performed after an elapse of a predetermined time from the supply stop of the deposition gas,
wherein the predetermined time is in a range of about 0.5 second to about 2 seconds.

9. The method of claim 7, wherein the mother substrate further includes a non-display area adjacent to the display area,
wherein, in the inorganic layer, a top surface of a portion which overlaps the display area and a top surface of a portion which overlaps the non-display area have a substantially identical surface roughness.

10. The method of claim 6, wherein the deposition gas includes a silane (SiH₄) gas.

11. The method of claim 6, wherein the preliminary inorganic layer includes:
a lower layer;
an upper layer on the lower layer; and
a silicon pattern on the upper layer,
wherein the removed portion of the preliminary inorganic layer includes the silicon pattern.

12. The method of claim 11, wherein forming the preliminary inorganic layer includes providing the deposition gas until the upper layer has a predetermined ratio of oxygen atoms to silicon atoms, the predetermined ratio being in a range of about 1.5 to about 5.

13. The method of claim 6, further comprising proving a liquid monomer on the inorganic layer to form an organic layer.

14. The method of claim 13, wherein the mother substrate further includes:
a first dam on the mother substrate and spaced apart from the organic emission element; and
a second dam on the mother substrate and farther away than the first dam from the organic emission element,
wherein the liquid monomer has fluidity capable of extending between the first dam and the second dam.

15. A method of fabricating a display panel, the method comprising:
providing a mother substrate on which is formed an organic emission element which includes an anode, an emission layer, and a cathode on a display area;
providing the mother substrate with plasma;
providing the display area with a deposition gas to form a preliminary inorganic layer;
stopping providing the deposition gas;
removing at least a portion of the preliminary inorganic layer to form an inorganic layer; and
removing the plasma,
wherein removing the plasma is performed after stopping providing the deposition gas.

16. The method of claim 15, wherein removing the plasma is performed after an elapse of a predetermined time from the supply stop of the deposition gas,
wherein the predetermined time is in a range of about 0.5 second to about 2 seconds.

17. The method of claim 15, wherein a surface roughness of the inorganic layer is equal to or less than about 4 nm.

18. The method of claim 15, wherein the mother substrate further includes a non-display area adjacent to the display area,
wherein, in the inorganic layer, a top surface of a portion which overlaps the display area and a top surface of a portion which overlaps the non-display area have a substantially identical surface roughness.

19. The method of claim 15, wherein the preliminary inorganic layer includes:
a lower layer;
an upper layer on the lower layer; and
a silicon pattern on the upper layer,
wherein a ratio of oxygen atoms to silicon atoms in the upper layer is greater than a ratio of oxygen atoms to silicon atoms in the lower layer, and
wherein the removed portion of the preliminary inorganic layer includes the silicon pattern.

20. The method of claim 19, wherein forming the preliminary inorganic layer includes providing the deposition gas such that the ratio of oxygen atoms to silicon atoms in the upper layer has a range of about 1.5 to about 5.
